(19) United States
(12) Patent Application Publication
(10) Pub. No.: US 2025/0316959 A1
(43) Pub. Date: Oct. 9, 2025

(54) Topological Laser and Method of Forming the Same

(71) Applicant: Nanyang Technological University, Singapore (SG)

(72) Inventors: Song HAN, Singapore (SG); Qijie WANG, Singapore (SG); Yun Da CHUA, Singapore (SG); Yongquan ZENG

(21) Appl. No.: 18/865,783

(22) PCT Filed: May 16, 2023
(86) PCT No.: PCT/SG2023/050332

§ 371 Date: Nov. 14, 2024

(30) Foreign Application Priority Data
Jun. 2, 2022 (SG) 10202250005W

(51) Int. Cl. H01S 5/11; H01S 5/34

(52) U.S. Cl. CPC H01S 5/11; H01S 5/3402; H01S 2301/18; H01S 2301/203; H01S 2302/02

(57) ABSTRACT

Various embodiments may provide a topological laser. The topological laser may include a photonic structure configured to generate a laser beam upon electrical pumping of the photonic structure. The laser beam may be based on photonic Majorana zero mode. The laser beam may be a cylindrical vector beam. The topological laser may be configured to provide single mode operation.

### CROSS-REFERENCE TO RELATED APPLICATION

This application claims the benefit of priority of Singapore application Ser. No. 10202250005W filed Jun. 2, 2022, the contents of it being hereby incorporated by reference in its entirety for all purposes.

### TECHNICAL FIELD

Various embodiments of this disclosure may relate to a topological laser. Various embodiments of this disclosure may relate to a method of forming a topological laser.

### BACKGROUND

In recent years, the concepts underlying topological quantum materials have inspired a variety of novel topological photonic devices. For example, topological lasers (TLs) have been realized in a variety of designs, including one-dimensional (1D) Su-Schrieffer-Heeger (SSH) lasers with localized topological modes, two-dimensional (2D) SSH lasers with corner modes, and 2D photonic crystal and coupled-resonator lasers with chiral edge modes. One of the most promising features of TLs is the insensitivity of their lasing modes to certain perturbations, which may reduce the impact of fabrication defects or environmental disturbances. Very recently, researchers have started to explore using TLs to form nontrivial emission patterns, such as vortex beams. In such lasers, the topological properties of the internal photonic modes can determine the far-field features of the laser light, including its topological structure. A photonic spin Hall insulator was optically pumped with a spatially tailored beam to generate a vortex beam carrying out-of-plane orbital angular momentum (OAM) has been previously reported. In another reported work, a laser with a high-order OAM beam was achieved using a photonic quantum Hall lattice biased by a strong external magnetic field. These approaches require either an external magnetic field or structured optical pumping, and thus far have only been used to realize vortex beams.

### SUMMARY

Various embodiments may provide a topological laser. The topological laser may include a photonic structure configured to generate a laser beam upon electrical pumping of the photonic structure. The laser beam may be based on photonic Majorana zero mode. The laser beam may be a cylindrical vector beam. The topological laser may be configured to provide single mode operation.

Various embodiments may relate to a method of forming a topological laser. The method may include forming a photonic structure configured to generate a laser beam upon electrical pumping of the photonic structure. The laser beam may be based on photonic Majorana zero mode. The laser beam may be a cylindrical vector beam. The topological laser may be configured to provide single mode operation.

### BRIEF DESCRIPTION OF THE DRA WINGS

In the drawings, like reference characters generally refer to the same parts throughout the different views. The drawings are not necessarily drawn to scale, emphasis instead generally being placed upon illustrating the principles of various embodiments. In the following description, various embodiments of the invention are described with reference to the following drawings.

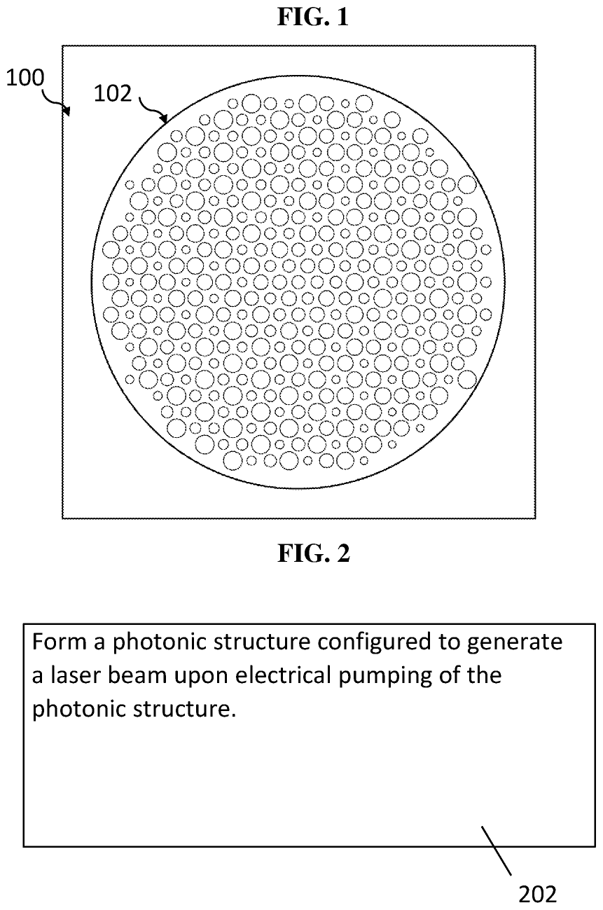

FIG. 1 is a schematic showing a topological laser (TL) according to various embodiments.

FIG. 2 is a schematic showing a method of forming a topological laser according to various embodiments.

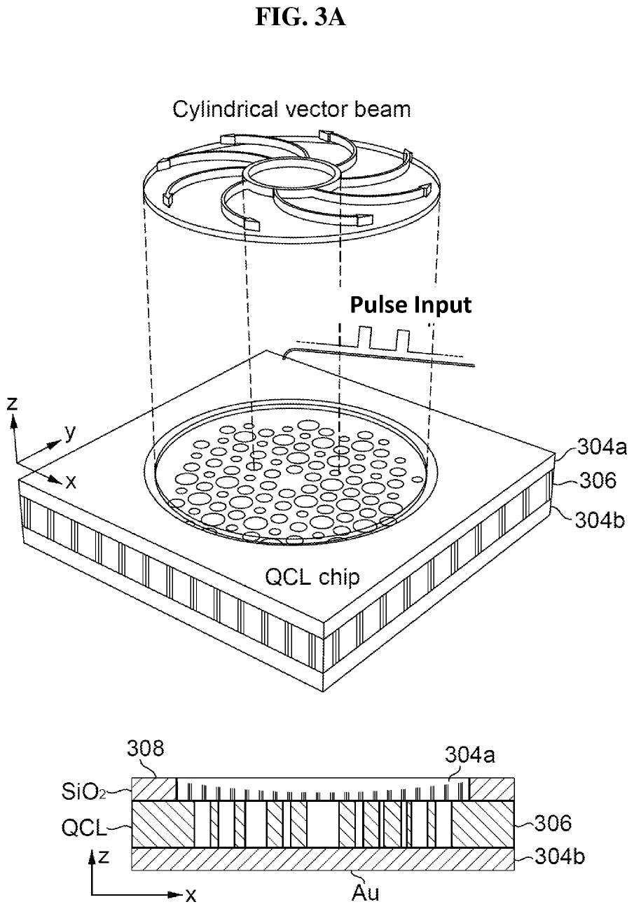

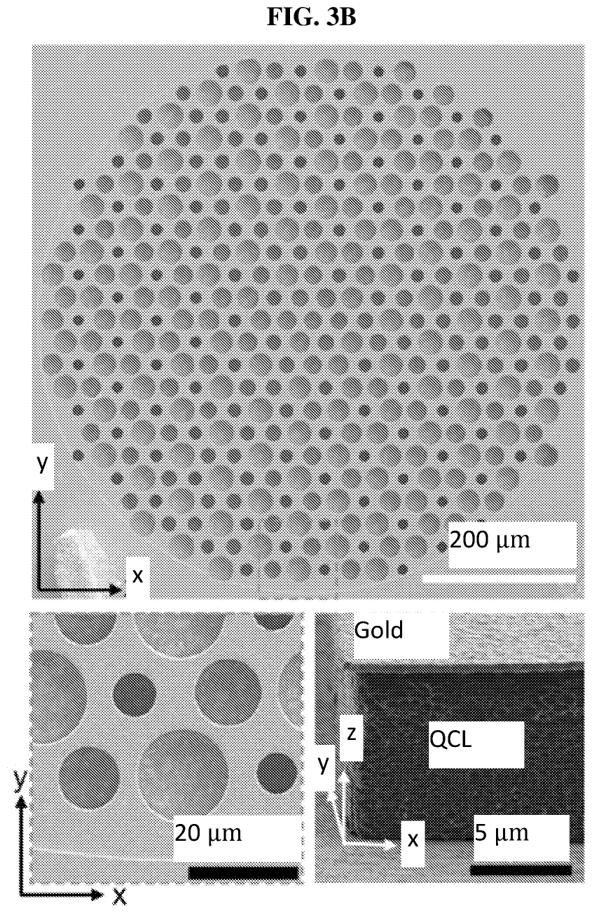

FIG. 3A is a schematic showing (top) a perspective view and (bottom) a cross-sectional side view of a topological laser according to various embodiments.

FIG. 3B shows the scanning electron microscopy (SEM) images of the fabricated laser according to various embodiments.

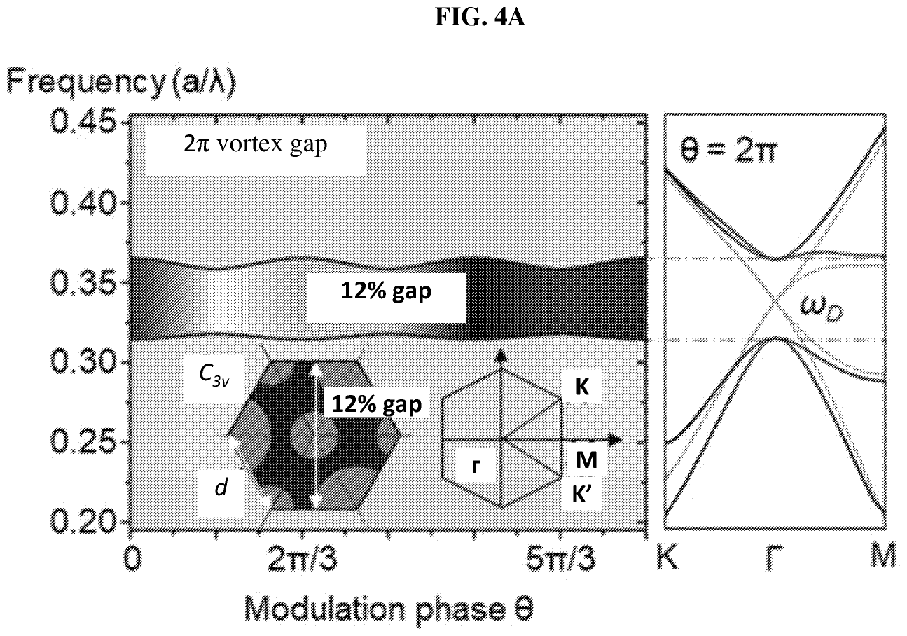

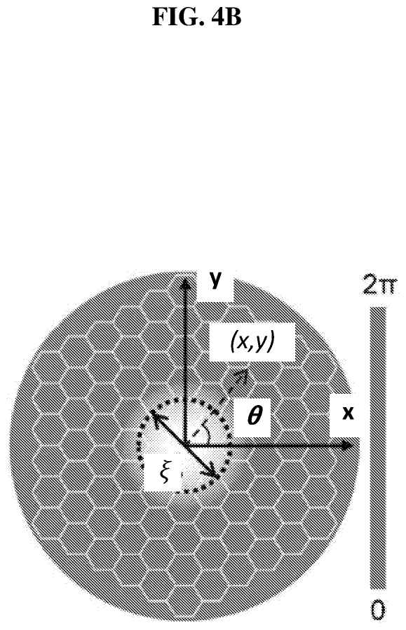

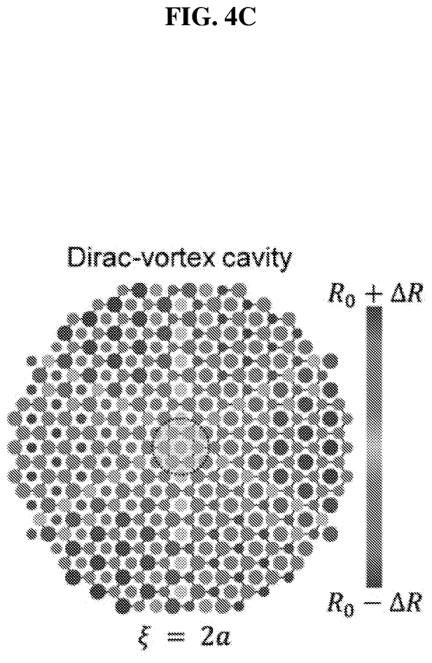

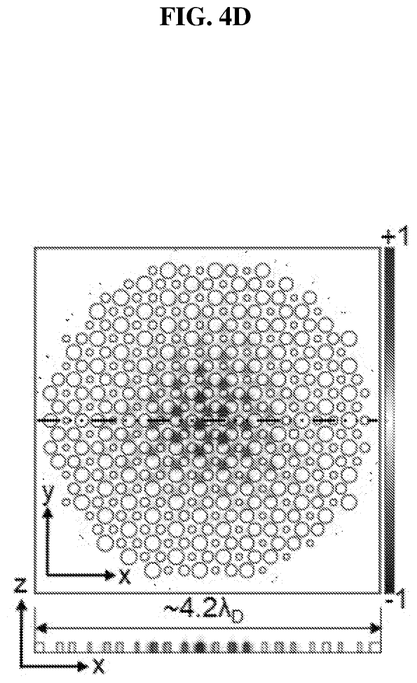

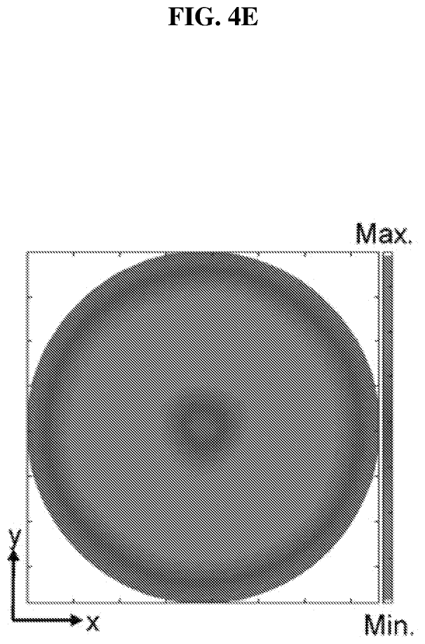

FIG. 4A is a plot of frequency (a/λ) as a function of modulation phase (θ) showing the band diagram of a hexagonal supercell with Kekulé modulation (left) and the unmodulated photonic crystal (right) according to various embodiments.

FIG. 4B is a schematic showing the phase of the Kekulé pattern having winding number (+1) according to various embodiments.

FIG. 4C is a schematic showing the modulation of the air hole radii of the photonic structure according to various embodiments, using a vortex core diameter of two periods (ξ=2a).

FIG. 4D shows the calculated electric field (E_{z}) for the photonic Majorana zero mode according to various embodiments, which is tightly confined to the vortex core.

FIG. 4E shows the calculated far-field intensity pattern of the photonic Majorana zero mode, which exhibits a doughnut-like profile characteristic of cylindrical vector (CV) beams according to various embodiments.

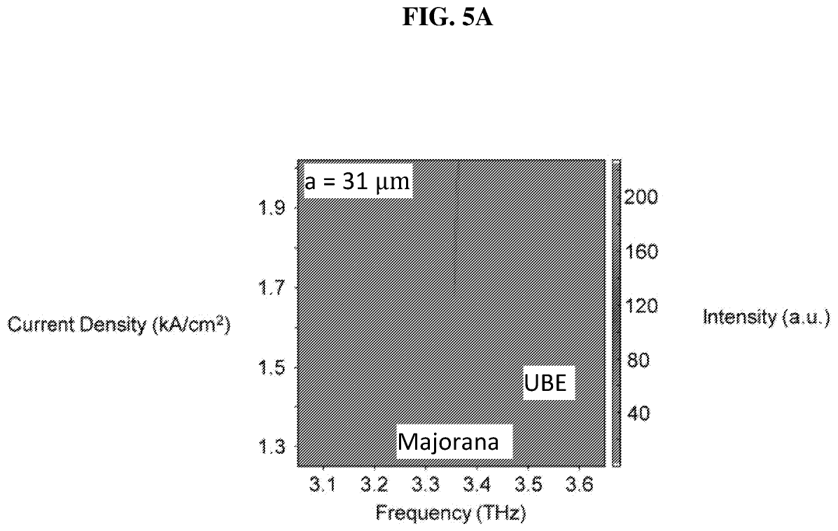

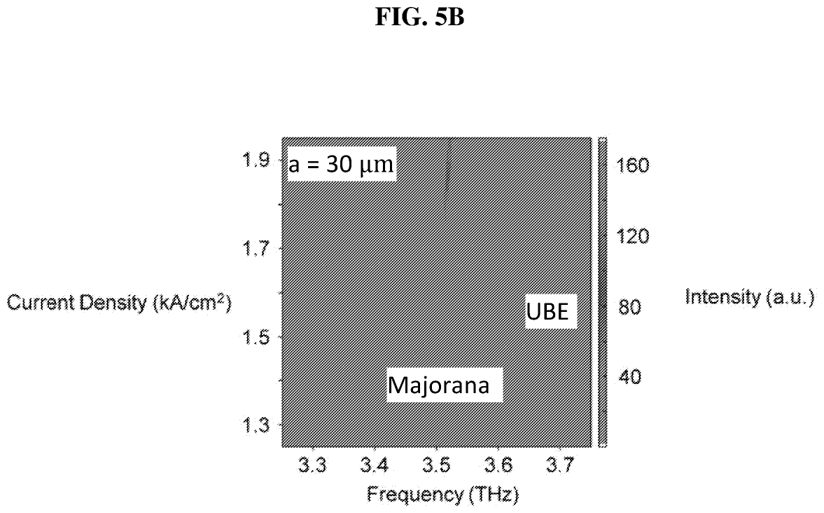

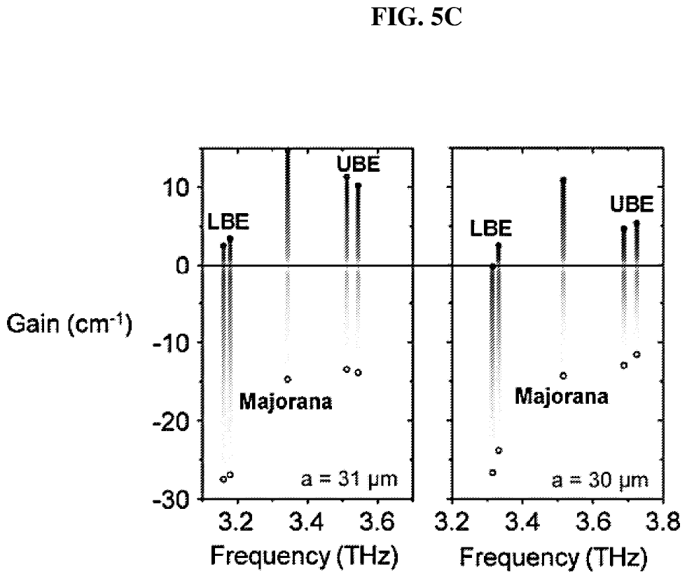

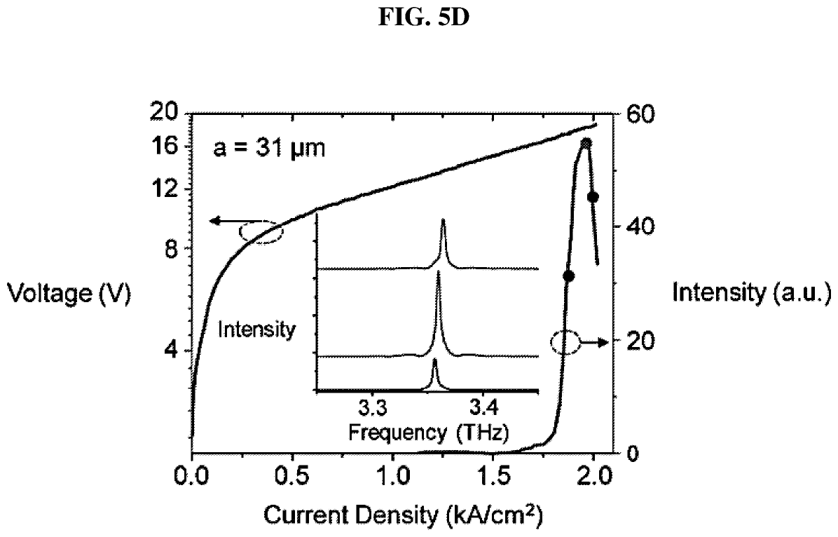

FIG. 5A is an emission intensity plot of current density (in kilo-Amperes per square centimetre or kA/cm²) as a function of frequency (in terahertz or THz) showing the emission intensity emission spectra for different pump current densities, obtained using a sample with lattice constant a=31 μm according to various embodiments.

FIG. 5B is an emission intensity plot of current density (in kilo-Amperes per square centimetre or kA/cm²) as a function of frequency (in terahertz or THz) showing the emission intensity emission spectra for different pump current densities, obtained using a sample with lattice constant a=30 μm according to various embodiments.

FIG. 5C shows plots of gain (per centimetre or cm⁻¹) as a function of frequency (in terahertz or THz) illustrating the calculated net gain coefficients before and after the laser devices are pumped according to various embodiments.

FIG. 5D shows a plot of voltage (in volts or V)/intensity (in arbitrary units or a.u.) as a function of current density (in kilo-Amperes per square centimetre or kA/cm²) illustrating the light-current-voltage (L-I-V) curve for the a=31 μm sample according to various embodiments; and (inset) a plot of intensity as a function of frequency (in terahertz or THz) showing an emission spectrum at the laser roll-over point according to various embodiments.

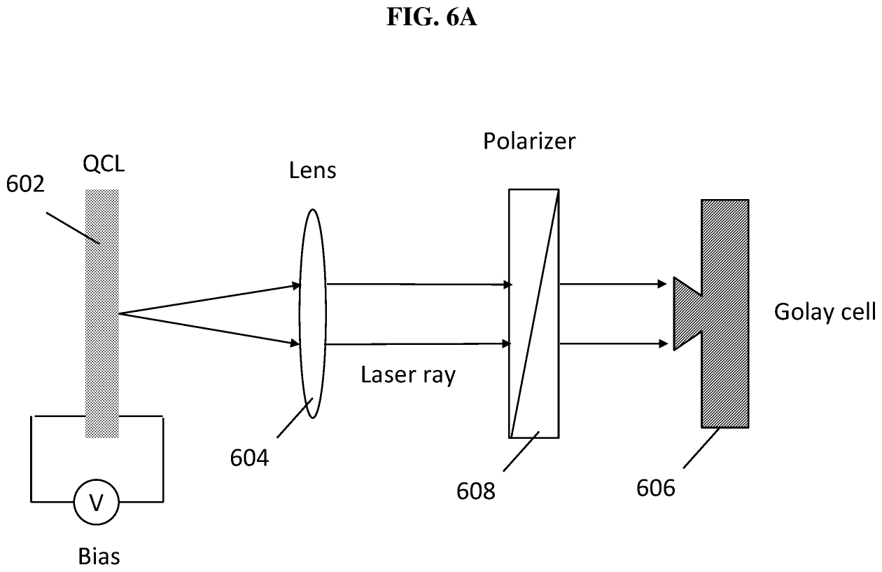

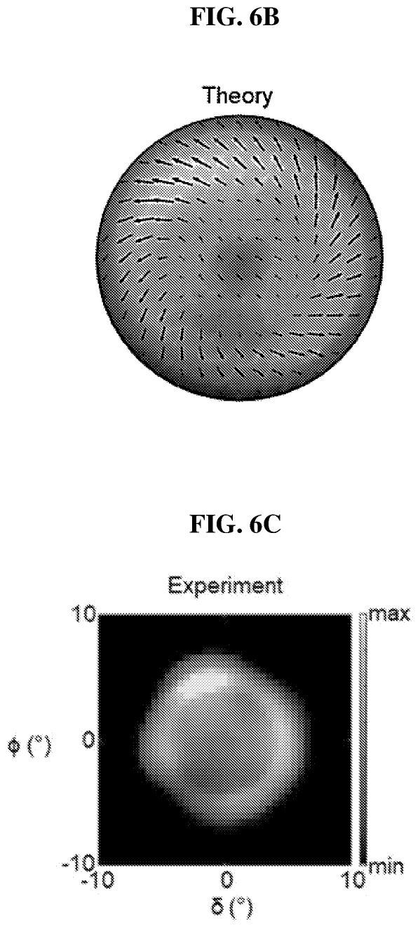

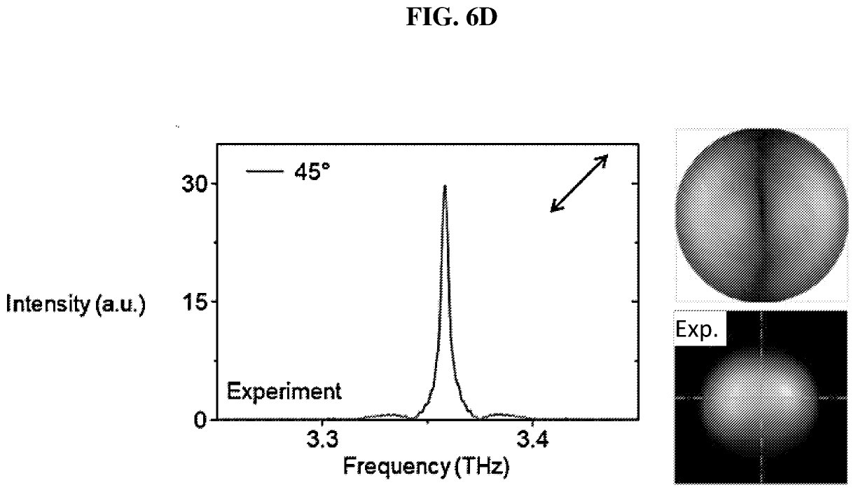

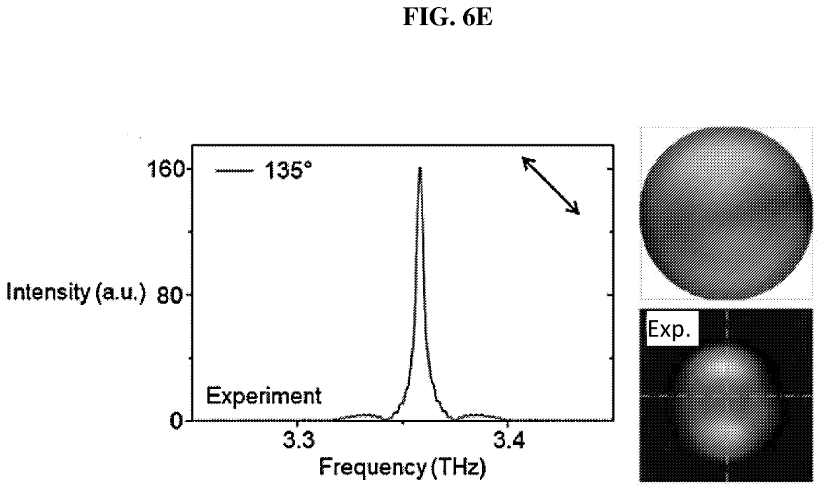

FIG. 6A is an image showing the experimental setup for far-field beam measurements according to various embodiments.

FIG. 6B shows a numerically calculated intensity profile according to various embodiments.

FIG. 6C shows an experimentally obtained intensity profile according to various embodiments.

FIG. 6D shows (left) a plot of intensity (in arbitrary units or a.u.) as a function of frequency (in terahertz or THz) illustrating results polarized-resolved emission spectra obtained by inserting a wire-grid polarizer with polarization angle of 45° between the focal lens and the terahertz detector according to various embodiments; and (right) numerically calculated (upper) and experimentally measured (lower) intensity patterns of the polarized-resolved emission spectra obtained according to various embodiments.

FIG. 6E shows (left) a plot of intensity (in arbitrary units or a.u.) as a function of frequency (in terahertz or THz) illustrating results polarized-resolved emission spectra obtained by inserting a wire-grid polarizer with polarization angle of 135° between the focal lens and the terahertz detector according to various embodiments; and (right) numerically calculated (upper) and experimentally measured (lower) intensity patterns of the polarized-resolved emission spectra obtained according to various embodiments.

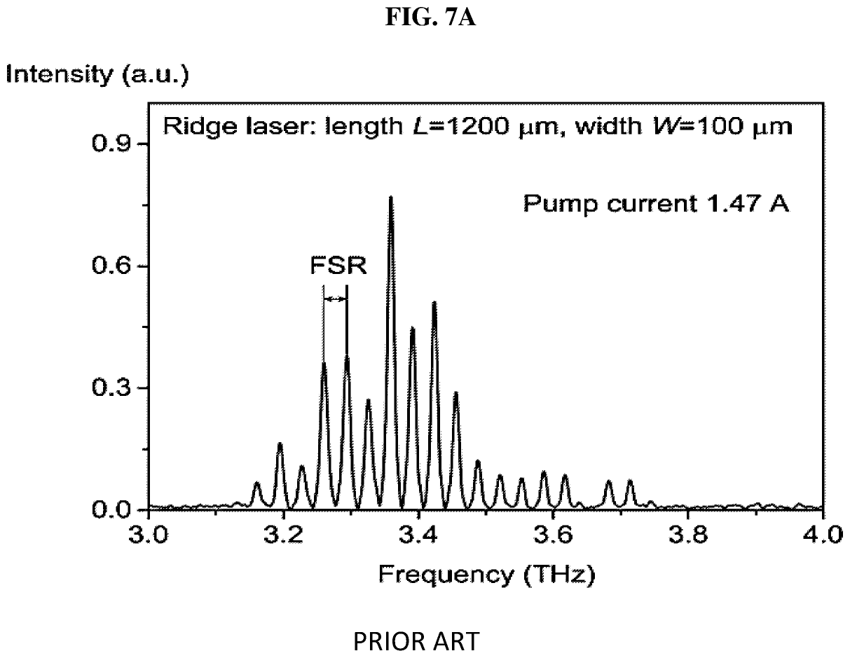

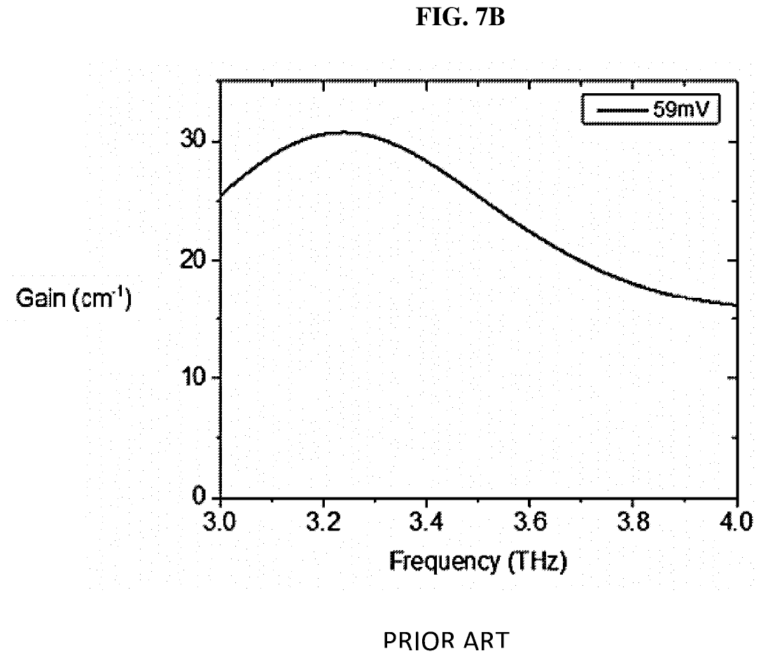

FIG. 7A shows a plot of intensity (in arbitrary units or a.u.) as a function of frequency (in terahertz or THz) illustrating the emission characteristics of a conventional laser with length of 1200 μm and width of 100 μm fabricated on the quantum cascade wafer.

FIG. 7B is a plot of gain (per centimetre or cm⁻¹) as a function of frequency (in terahertz or THz) illustrating the calculated gain profile for the quantum cascade laser (QCL) with one period of 44 nm in thickness

FIG. 8 shows the band structure of the photonic lattice according to various embodiments with different relative hopping amplitudes of t₁ and t₂.

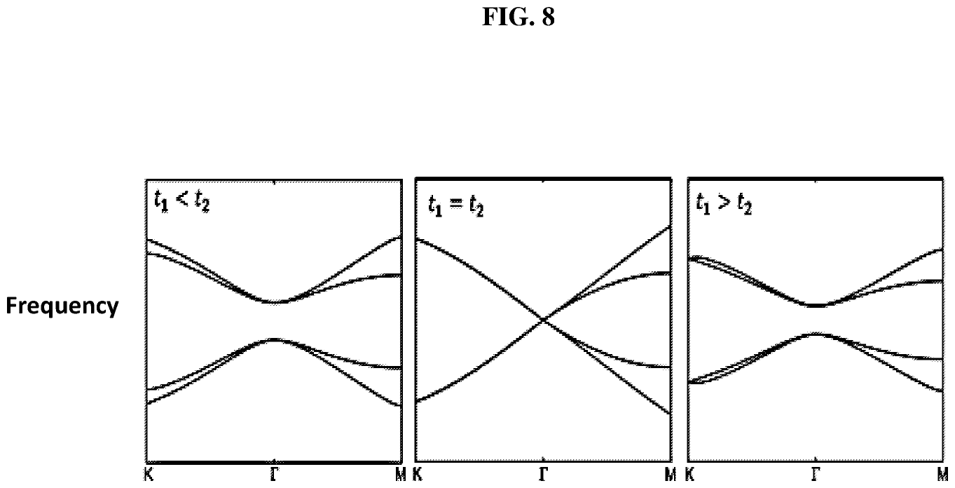

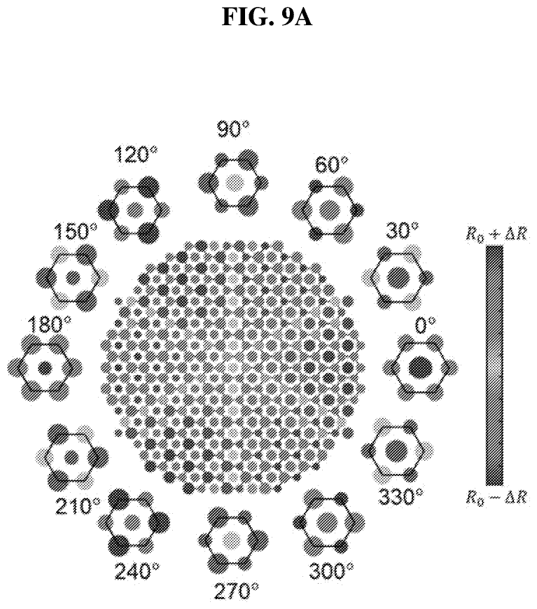

FIG. 9A shows the bulk band structures at fixed phases from 0 to 2π with a step of π/6 according to various embodiments.

FIG. 9B shows a plot of frequency (a/λ) as a function of modulation phase (θ) illustrating the band diagrams of the bulk band structures according to various embodiments.

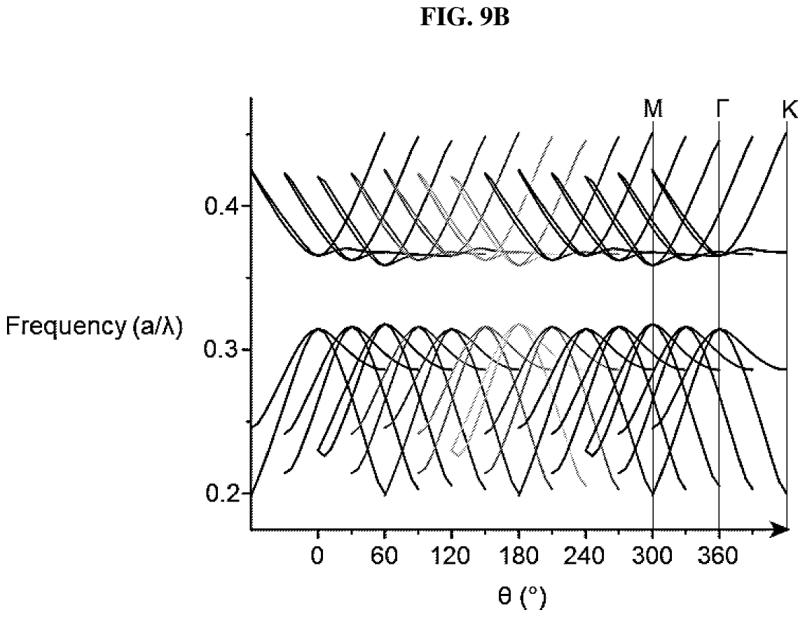

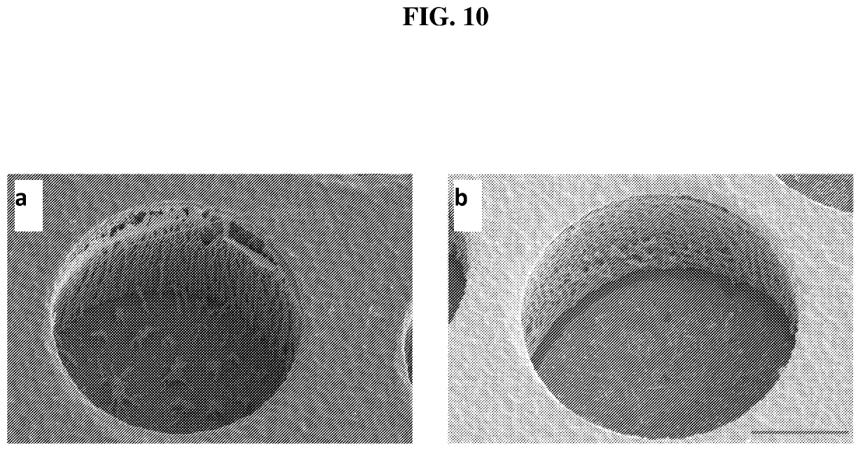

FIG. 10 shows scanning electron microscopy (SEM) images of (a) the fabricated samples before acid etching according to various embodiments; and (b) the fabricated samples after acid etching according to various embodiments.

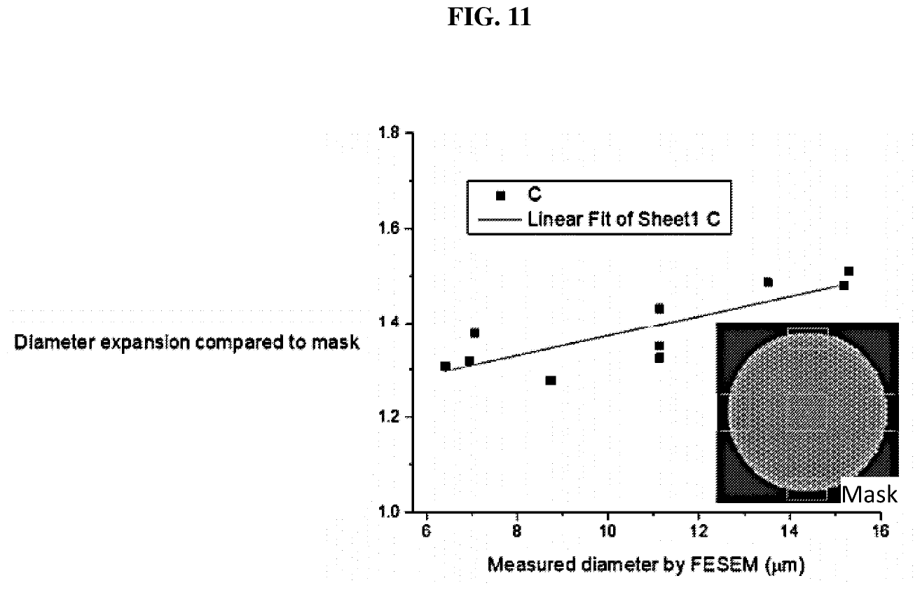

FIG. 11 shows a plot of diameter of expansion compared to mask as a function of measured diameter by field emission scanning electron microscopy (FESEM) illustrating the fitting of the linear function to the measured values according to various embodiments, with the inset showing the five regions for the fabricated sample according to various embodiments analysed by the microscope and compared to the designed mask.

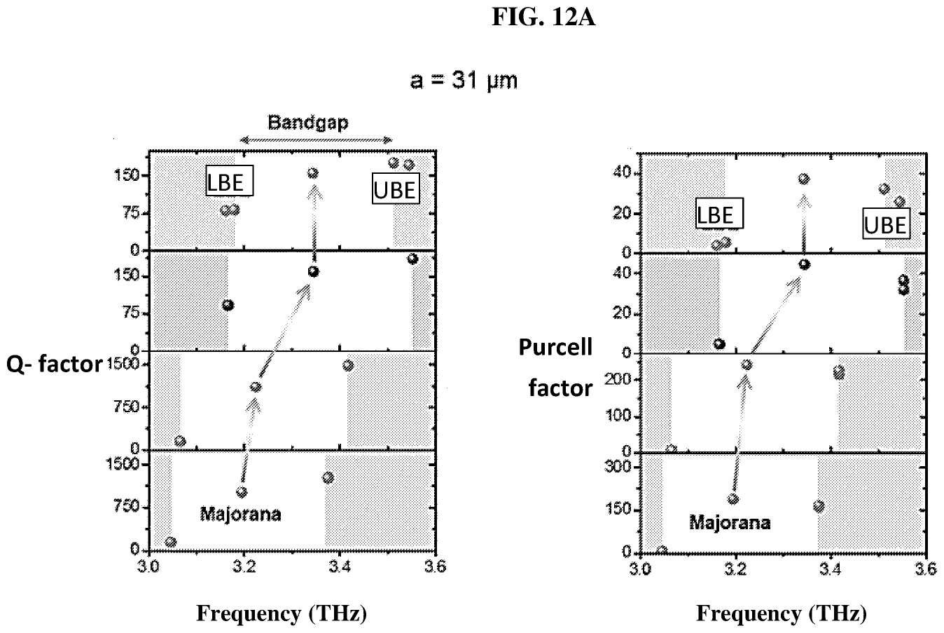

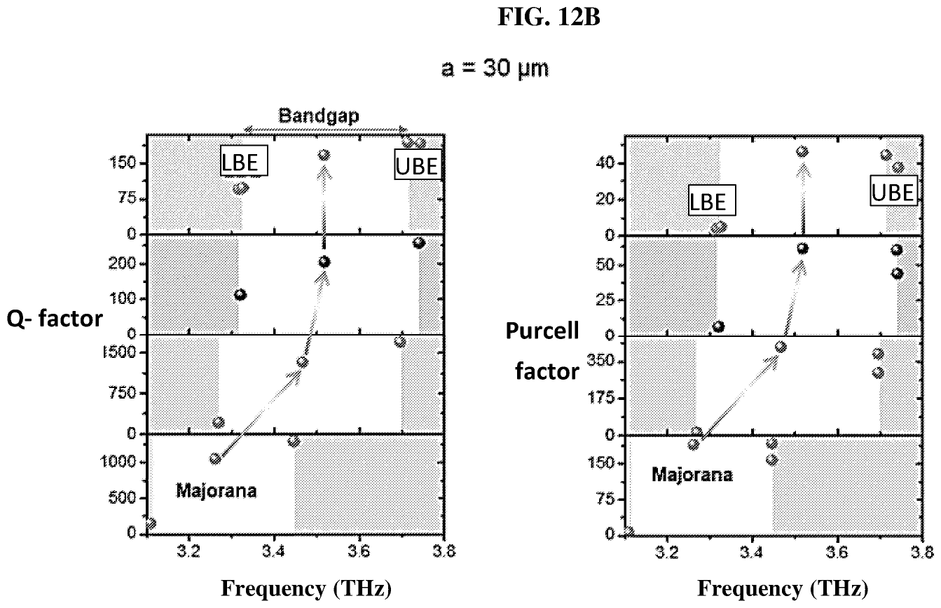

FIG. 12A shows (left) plots of Q-factor as a function of frequency (in terahertz or THz) and (right) plots of Purcell factor as a function of frequency (in terahertz or THz) of the sample with lattice constant of 31 μm according to various embodiments illustrating, from bottom to top, the calculated eigenmodes of perfect electric conductor (PEC) cladded Dirac-vortex cavity without expansion, PEC cladded Dirac-vortex cavity with expansion, gold (Au) Drude model cladded Dirac-vortex cavity with expansion and radius of air holes in quantum cascade wafer-radius of air holes in gold layers (r_{QCL}-r_{Au}), gold (Au) Drude model cladded Dirac-vortex cavity with expansion, anisotropy (semi-major axis by semi-minor axis equals to 1.05, and orientation along y-axis).

FIG. 12B shows (left) plots of Q-factor as a function of frequency (in terahertz or THz) and (right) plots of Purcell factor as a function of frequency (in terahertz or THz) of the sample with lattice constant of 30 μm according to various embodiments illustrating, from bottom to top, the calculated eigenmodes of perfect electric conductor (PEC) cladded Dirac-vortex cavity without expansion, PEC cladded Dirac-vortex cavity with expansion, gold (Au) Drude model cladded Dirac-vortex cavity with expansion and radius of air holes in quantum cascade wafer—radius of air holes in gold layers (r_{QCL}-r_{Au})=400 nm, gold (Au) Drude model cladded Dirac-vortex cavity with expansion, anisotropy (semi-major axis by semi-minor axis equals to 1.05, and orientation along y-axis).

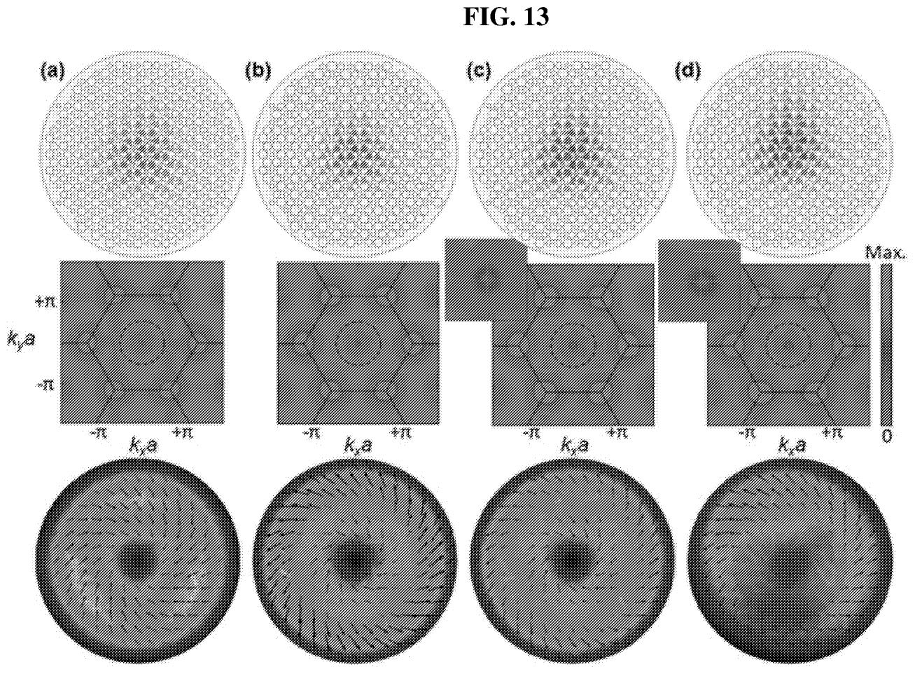

FIG. 13 shows (top panel) the electric field z-component at the middle of the Dirac-vortex cavity according to various embodiments; (middle panel) Fourier transformed electric field (FT(E_{z})) according to various embodiments; and (bottom panel) the far-field beam patterns according to various embodiments.

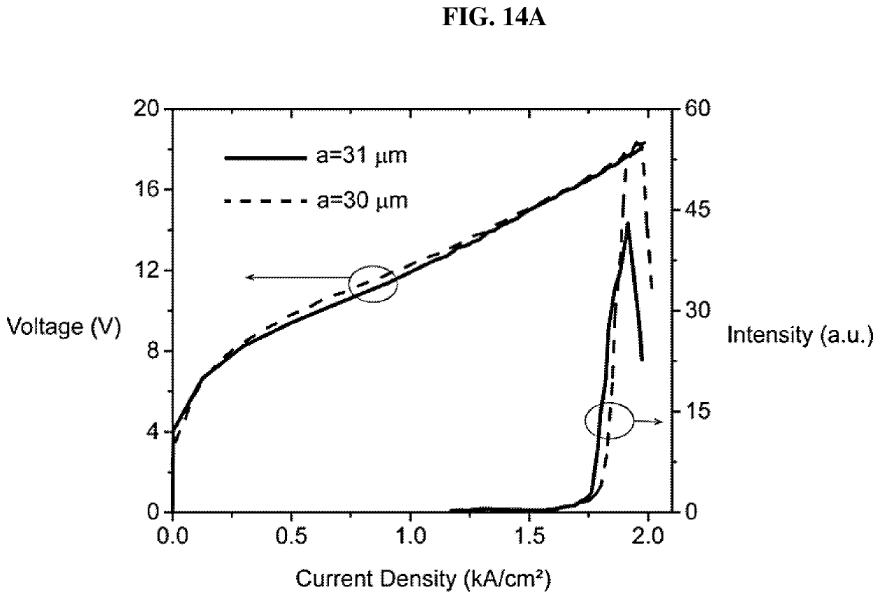

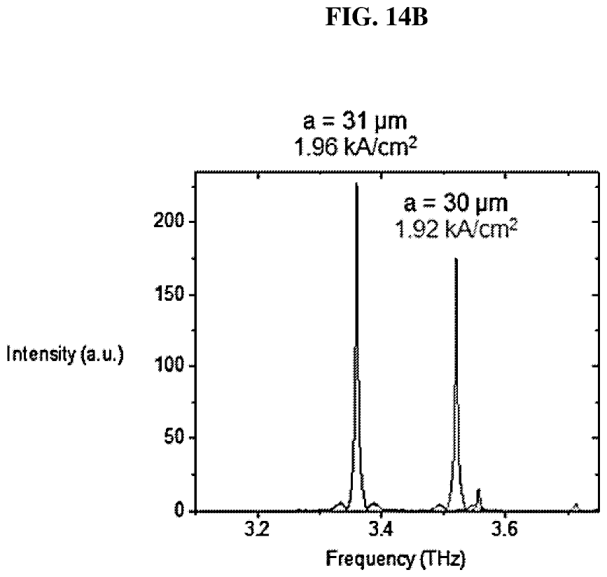

FIG. 14A shows a plot of voltage (in volts or V)/intensity (in arbitrary units or a.u.) as a function of current density (in kiloamperes per square centimetre or kA/cm²) illustrating the light-current-voltage (L-I-V) curve comparison between two samples with lattice constants of 31 μm and 30 μm according to various embodiments.

FIG. 14B shows a plot of intensity (in arbitrary units or a.u.) as a function of frequency (in terahertz or THz) illustrating the emission spectra measured at similar bias voltage and pump current density for vortex lasers with lattice constants of 31 μm and 30 μm according to various

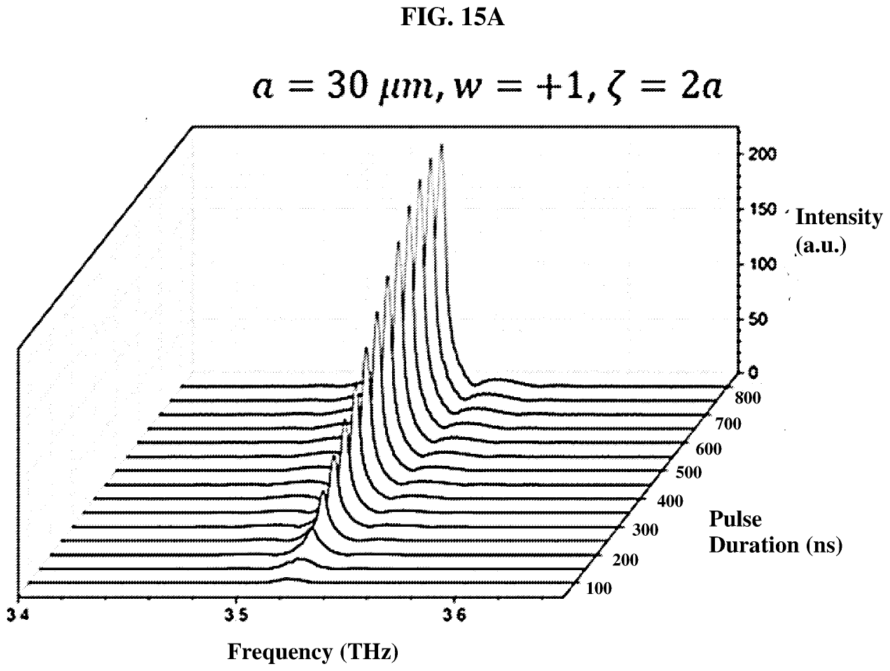

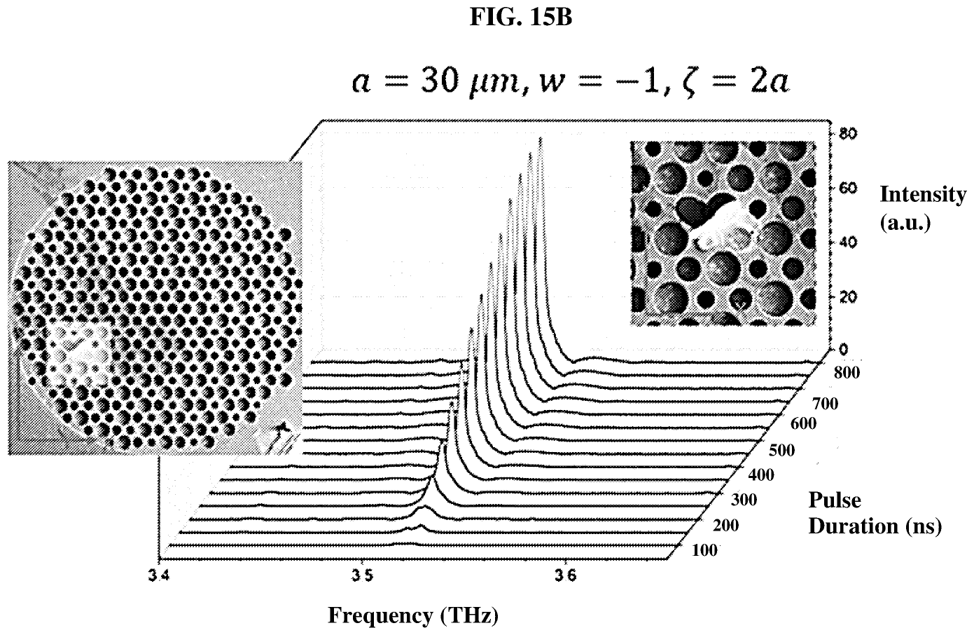

FIG. 15A is a three-dimensional (3D) plot of intensity (in arbitrary units or a.u. as a function of frequency (in terahertz or THz) and pulse duration (in nanoseconds or ns) illustrating the robustness of the single-mode quantum cascade laser (QCL) with winding number +1 without defect according to various embodiments.

FIG. 15B is a three-dimensional (3D) plot of intensity (in arbitrary units or a.u. as a function of frequency (in terahertz or THz) and pulse duration (in nanoseconds or ns) illustrating the robustness of the single-mode quantum cascade laser (QCL) with winding number −1 with accidental defects due to fabrications according to various embodiments, with the inset showing the scanning electron microscopy (SEM) images of the defects.

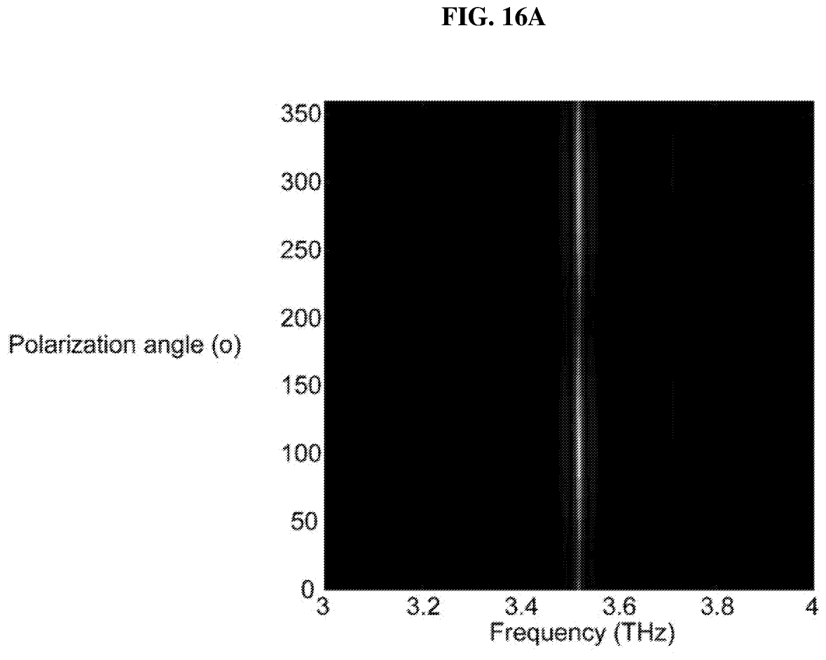

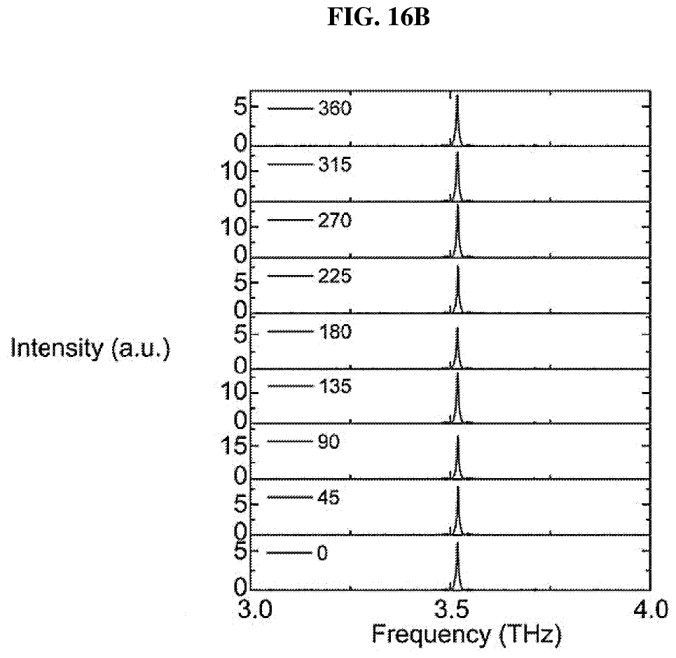

FIG. 16A shows a plot of polarization angle (in degrees or °) as a function of frequency (in terahertz or THz) of the polarization lasing spectra for a sample with lattice constant a=30 μm according to various embodiments.

FIG. 16B shows a plot of intensity (in arbitrary units or a.u.) as a function of frequency (in terahertz or THz) of the polarization lasing spectra for the sample with lattice constant a=30 μm according to various embodiments.

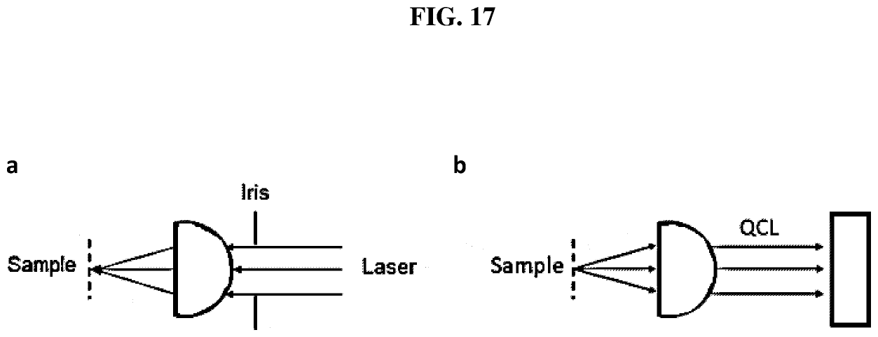

FIG. 17 shows (a) a schematic of a focal system being inserted between the terahertz (THz) quantum cascade laser (QCL) sample and iris, where the focused light should be on same position of the THz QCL sample according to various embodiments; and (b) a schematic of an electrically pumped quantum cascade laser (QCL) with the laser pointer replaced by a terahertz (THz) Golay cell detector for far-field mapping according to various embodiments.

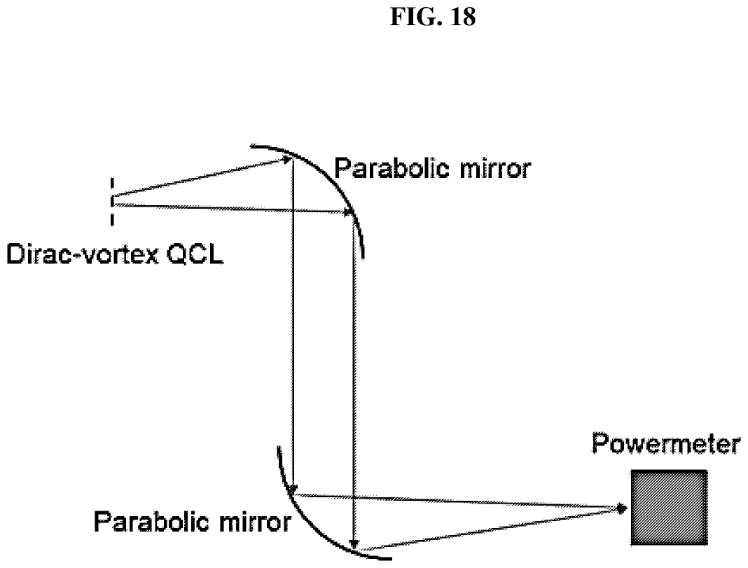

FIG. 18 shows a setup for focusing the diverged beam of the Dirac-vortex quantum cascade laser (QCL) according to various embodiments.

### DESCRIPTION

The following detailed description refers to the accompanying drawings that show, by way of illustration, specific details and embodiments in which the invention may be practised. These embodiments are described in sufficient detail to enable those skilled in the art to practise the invention. Other embodiments may be utilized and structural, logical, and electrical changes may be made without departing from the scope of the invention. The various embodiments are not necessarily mutually exclusive, as some embodiments can be combined with one or more other embodiments to form new embodiments.

Features that are described in the context of an embodiment may correspondingly be applicable to the same or similar features in the other embodiments. Features that are described in the context of an embodiment may correspondingly be applicable to the other embodiments, even if not explicitly described in these other embodiments. Furthermore, additions and/or combinations and/or alternatives as described for a feature in the context of an embodiment may correspondingly be applicable to the same or similar feature in the other embodiments.

In the context of various embodiments, the articles “a”, “an” and “the” as used with regard to a feature or element include a reference to one or more of the features or elements.

In the context of various embodiments, the term “about” or “approximately” as applied to a numeric value encompasses the exact value and a reasonable variance, e.g., within 10% of the specified value.

As used herein, the term “and/or” includes any and all combinations of one or more of the associated listed items.

By “comprising” it is meant including, but not limited to, whatever follows the word “comprising”. Thus, use of the term “comprising” indicates that the listed elements are required or mandatory, but that other elements are optional and may or may not be present.

By “consisting of” is meant including, and limited to, whatever follows the phrase “consisting of”. Thus, the phrase “consisting of” indicates that the listed elements are required or mandatory, and that no other elements may be present.

Embodiments described in the context of one of the topological lasers (TLs) are analogously valid for the other topological lasers. Similarly, embodiments described in the context of a method are analogously valid for a topological laser, and vice versa.

It may be desirable to develop an electrically pumped topological laser (TL) that can convert electrical energy directly to a laser beam with nontrivial structure.

FIG. 1 is a schematic showing a topological laser (TL) 100 according to various embodiments. The topological laser 100 may include a photonic structure 102 configured to generate a laser beam upon electrical pumping of the photonic structure 102. The photonic structure 102 may be configured to generate a laser beam upon electrical pumping of the photonic structure 102. The laser beam may be based on photonic Majorana zero mode. The laser beam may be a cylindrical vector (CV) beam. The topological laser 100 may be configured to provide single mode operation.

In other words, various embodiments may relate to an electrically pumped topological laser 100 which is configured to generate a single mode cylindrical vector (CV) beam based on photonic Majorana zero mode upon application of a pump current.

For avoidance of doubt, FIG. 1 is intended to illustrate some features of a topological laser 100 according to various embodiments, and is not intended to limit the size, shape, orientation etc. of the laser 100 or a component of the laser 100.

The topological laser 100 may alternatively be referred to as a vortex laser, a quantum cascade laser (QCL), a quantum cascade laser (QCL) device, or a laser device. The large circular area 102 may denote the pump region, while the small circles within the circular area 102 may be the air holes for photonic configuration and surface emission. The square area may indicate the entire laser.

In various embodiments, the photonic structure 102 may include a first electrically conductive layer (e.g., a first metal layer) and a second electrically conductive layer (e.g., a second metal layer). The photonic structure 102 may also include a photonic lattice between the first electrically conductive layer (e.g., the first metal layer) and the second electrically conductive layer (e.g., the second metal layer). The photonic structure 102 or photonic lattice may support traverse magnetic (TM) polarized modes.

In various embodiments, the first electrically conductive layer (e.g., the first metal layer) and the photonic lattice layer include a plurality of air holes extending from the first electrically conductive layer (e.g., the first metal layer) to the photonic lattice layer. The plurality of airholes may extend from an exposed surface of the first electrically conductive layer (e.g., the first metal layer) to a surface of the photonic lattice layer adjoining the second electrically conductive layer (e.g., the second metal layer) or to within the photonic lattice layer. The air holes may alternatively be referred to as air cylinders. The airholes may, for instance, be cylindrical or elliptical airholes. In other words, the shape of the airholes as seen on the exposed surface of the first electrically conductive layer may be circular or elliptical,

In various embodiments, each of the plurality of air holes may have a radius dependent on a position of the air hole according to a Kekulé modulation. In other words, the plurality of air holes may not have the same radius.

In various embodiments, the plurality of air holes may form a honeycomb lattice arrangement. An air hole (in a central portion of the photonic lattice layer) of the plurality of air holes may be surrounded by six other air holes of plurality of air holes. In other words, the air holes (except the ones at the border region) may have six neighbouring air holes.

In various embodiments, the photonic Majorana zero mode may be a mid-gap state occurring in the photonic structure 102 or photonic lattice. The photonic Majorana zero mode may be formed by a honeycomb lattice arrangement with a chiral Kekulé modulation. The Majorana zero mode may be useful for lasing because the frequency of the Majorana zero mode is pinned to the centre of the photonic bandgap (i.e. between the conduction band and the valence band) of the photonic bandgap. The intrinsic chirality of the photonic Majorana zero mode may generate a non-trivial far-field emission pattern. The cylindrical vector (CV) beam generated may have a doughnut-like profile.

In various embodiments, the photonic structure 102 may further include an electrically insulating layer surrounding the first electrically conductive layer (e.g., the first metal layer). For instance, the electrically insulating layer may include silicon dioxide or silicon nitride. The insulating layer may further extend below the first electrically conductive layer such that the first electrically conductive layer is on a portion of the insulating layer.

In various embodiments, the first metal layer and/or the second metal layer may include any suitable metal that forms an ohmic contact with a semiconductor material included in the photonic lattice layer. In various embodiments, the first metal layer and/or the second metal layer may include gold or copper.

In various embodiments, the photonic lattice may be or may include a quantum cascade laser (QCL) wafer or layer. The quantum cascade laser (QCL) wafer or layer may include alternate layers or sub-layers of a first semiconductor material and a second conductive material, thereby forming multiple quantum wells which allows for intersubband electron transitions. For instance, the QCL wafer or layer alternate layers or sub-layers of gallium arsenide (GaAs) and aluminium gallium arsenide (AlGaAs, e.g., Al_{0.15}Ga_{0.85}As). In another example, the QCL wafer or layer may include alternate layers or sub-layers of gallium indium arsenide (GaInAs) and aluminium indium arsenide (AlInAs). In yet another example, the QCL wafer or layer may include alternate layers or sub-layers of indium arsenide (InAs) and aluminium antimonide (AlSb).

In various embodiments, the photonic lattice may be configured to emit the beam upon application of a potential difference or voltage between the first electrically conductive layer (e.g., the first metal layer) and the second electrically conductive layer (e.g., the second metal layer). The potential difference or voltage applied between the first electrically conductive layer (e.g., the first metal layer) and the second electrically conductive layer (e.g., the second metal layer) may result in a pump current flowing through the photonic lattice. In other words, the photonic lattice may be radiative upon application of the potential difference or voltage.

In various embodiments, a centre of the laser beam may have a polarization singularity.

In various embodiments, the topological laser may be a terahertz (THz) semiconductor laser.

Various embodiments may relate to a laser possessing or including an electric pump.

Various embodiments may enable high power emission and manipulation of polarization winding through electrical pumping.

FIG. 2 is a schematic showing a method of forming a topological laser according to various embodiments. The method may include, in 202, forming a photonic structure configured to generate a laser beam upon electrical pumping of the photonic structure. The laser beam may be based on photonic Majorana zero mode. The laser beam may be a cylindrical vector beam. The topological laser may be configured to provide single mode operation.

In other words, various embodiments may relate to a method of forming a topological laser which generates a single mode, cylindrical vector beam based on photonic Majorana zero mode.

In various embodiments, forming the photonic structure may include forming a photonic lattice between a first electrically conductive layer (e.g., a first metal layer) and a second electrically conductive layer (e.g., a second metal layer). Forming the photonic structure may also include forming a plurality of air holes extending from the first electrically conductive layer (e.g., the first metal layer) to the photonic lattice.

In various embodiments, each of the plurality of air holes may have a radius dependent on a position of the air hole according to a Kekulé modulation.

In various embodiments, the plurality of air holes may form a honeycomb lattice arrangement.

In various embodiments, forming the photonic structure further may include forming an electrically insulating layer surrounding the first electrically conductive layer (e.g., the first metal layer). For instance, the electrically insulating layer may include silicon dioxide or silicon nitride.

In various embodiments, the first metal layer and/or the second metal layer may include gold, platinum or silver.

In various embodiments, the photonic lattice may be or may include a quantum cascade laser (QCL) wafer or layer.

In various embodiments, a centre of the laser beam may have a polarization singularity.

In various embodiments, the topological laser may be a terahertz (THz) semiconductor laser.

Various embodiments may relate an electrically pumped TL based on a photonic analogue of a Majorana zero mode, possessing a nontrivial polarization-winding emission profile corresponding to a CV beam. The photonic Majorana zero mode is a spectrally isolated mid-gap state occurring in a photonic structure formed by a honeycomb lattice with a chiral Kekulé modulation. The modes may be described by a two-dimensional 2D Dirac equation with mass vortex, and may be shown to have the existence of a zero-energy (i.e., mid-gap) solution which is topologically protected by the winding of the mass vortex. In the photonic context, this Majorana zero mode may be useful for lasing because its frequency is pinned to the centre of the photonic bandgap, and also because, as further discussed below, its intrinsic chirality may generate a nontrivial far-field emission pattern. The TL cavity may be implemented with a monolithic quantum cascade laser (QCL) wafer, based on intersubband electron transitions within multiple quantum wells. Unlike previous TLs which required careful tailoring of the pumping region to avoid unwanted lasing modes, various embodiments may only be required to be electrically pumped using simple top and bottom metal contacts covering the entire laser device. The mid-gap Majorana laser mode may be identified by spectral scanning over the full dynamic range of the laser, and far-field measurements may reveal a doughnut-shaped laser beam with a polarization singularity at the beam centre, characteristic of a CV beam. This compact and efficient laser, with at-source CV beam profile, may have potential applications for terahertz (THz) Light Detection and Ranging (LIDAR), imaging, microscopy, and wireless communications.

### Results

### Theoretical Model and Sample Fabrication

FIG. 3A is a schematic showing (top) a perspective view and (bottom) a cross-sectional side view of a topological laser according to various embodiments. The topological laser may be an electrically pumped quantum cascade laser (QCL) based on a photonic Majorana zero mode, which an array of air holes patterned into the top metal (e.g., gold or Au) layer 304a and the underlying QCL wafer 306. The QCL wafer 306 may form the photonic lattice. The top and bottom metal (e.g., gold or Au) layers 304a, 304b may function as electrical conductors for injection of pulsed pump current, as well as low loss modal confinement in the vertical direction due to the small Ohmic losses at terahertz frequencies. The region outside the cavity may be insulated by an electrically insulating (e.g., silicon dioxide or SiO₂) layer 308. The insulating layer 308 may also extend under the top metal layer 304a such that the insulating layer 308 is between the top metal layer 304a and the QCL wafer 306.

Since the photonic lattice or QCL wafer 306 is cladded by double metal layers 304a, 304b, the photonic lattice or QCL wafer 306 may support transverse magnetic (TM) polarized modes. The pump current may be supplied by a wire bonding pad insulated by the thick insulating (e.g., silicon dioxide or SiO₂) layer 308, which can be seen in the scanning electron microscope (SEM) image in FIG. 3B. FIG. 3B shows the scanning electron microscopy (SEM) images of the fabricated laser according to various embodiments. The laser has a photonic lattice constant a=31 μm, winding number w=+1, vortex core diameter ξ=2a, and an overall radius of six periods. The side view of the SEM shows that the QCL may be undercut relative to the top gold (Au) layer 304a.

In the pristine lattice (with lattice constant a, side length d=a/\sqrt{3}, and air holes having uniform radius R₀=0.35d), the photonic crystal may exhibit doubly degenerate Dirac cones, or “valleys”, at wavevectors K_{±}=[+4π/3d, 0] and frequency ω_{D}. FIG. 4A is a plot of frequency (a/λ) as a function of modulation phase (θ) showing the band diagram of a hexagonal supercell with Kekulé modulation (left) and the unmodulated photonic crystal (right) according to various embodiments. λ represents the wavelength. The bandgap may have ≥12% relative width. The inset shows the schematic of the hexagonal supercell and its Brillouin zone.

As mentioned above, a vortex-like Kekulé modulation may be overlaid on over the lattice, in the form of position-dependent air hole radii obeying

$$R ( r ) = {R}_{0} + Δ R ( r ) cos [ K \cdot r + θ ( r ) ] , \qquad ( 1 )$$

where K=K₊−K₋, r=(x, y) is the position vector in Cartesian coordinates, ΔR(r)=ΔR tanh(r/ξ) is a radial profile, ξ=2a is the vortex core diameter, and θ(r)=wtan⁻¹(y/x) is a position-dependent phase factor with winding number w=+1, as shown in FIG. 4B. FIG. 4B is a schematic showing the phase of the Kekulé pattern having winding number (+1) according to various embodiments. The resulting variation in the air hole radii is plotted in FIG. 4C. FIG. 4C is a schematic showing the modulation of the air hole radii of the photonic structure according to various embodiments, using a vortex core diameter of two periods (ξ=2a). The Kekulé modulation may induce intervalley coupling and may open a bandgap around ω_{D} of around 12% bandwidth, as shown in FIG. 4A. The Jackiw-Rossi binding mechanism may generate a photonic Majorana zero mode that is tightly localized to the vortex core, as verified by numerical simulations (FIG. 4D). FIG. 4D shows the calculated electric field (E_{z}) for the photonic Majorana zero mode according to various embodiments, which is tightly confined to the vortex core. The breaking of the photonic crystal's inversion symmetry (from C₆ᵥ to C₃ᵥ) may also result in radiative coupling to the out-of-plane continuum, and numerical simulations reveal that the photonic Majorana mode has a doughnut-shaped intensity profile in the far field (FIG. 4E). FIG. 4E shows the calculated far-field intensity pattern of the photonic Majorana zero mode, which exhibits a doughnut-like profile characteristic of cylindrical vector (CV) beams according to various embodiments.

### Experimental Results

The THz QCL wafer supplies gain over the 2.9 THz to 3.8 THz range, which overlaps with the designed photonic bandgap. Two different laser devices with lattice constants a=31 μm and a=30 μm were fabricated. The fabricated laser devices may be referred to as samples. Their measured emission spectra at various pumping current densities are plotted in FIG. 5A and FIG. 5B, respectively. FIG. 5A is an emission intensity plot of current density (in kilo-Amperes per square centimetre or kA/cm²) as a function of frequency (in terahertz or THz) showing the emission intensity emission spectra for different pump current densities, obtained using a sample with lattice constant a=31 μm according to various embodiments. FIG. 5B is an emission intensity plot of current density (in kilo-Amperes per square centimetre or kA/cm²) as a function of frequency (in terahertz or THz) showing the emission intensity emission spectra for different pump current densities, obtained using a sample with lattice constant a=30 μm according to various embodiments.

With increasing pump, each emission spectrum envelope undergoes a gradual blueshift, due to the Stark shift of the intersubband transition in the THz QCL medium. The Majorana zero mode peaks can nonetheless be clearly identified, which lie at 3.36 THz for the a=31 μm sample and 3.52 THz for the a=30 μm sample, very close to the predicted mid-gap frequency. A weaker emission peak at 3.56 THz and 3.71 THz may also be observed for the two respective samples. These may be identified as upper band edge (UBE) modes since they occur at the upper edge of the bandgap as predicted by numerical calculations. These experimental results are also consistent with numerical calculations of the modal net gain coefficients (FIG. 5C; see Supplementary Information below for details about these calculations). FIG. 5C shows plots of gain (per centimetre or cm⁻¹) as a function of frequency (in terahertz or THz) illustrating the calculated net gain coefficients before and after the laser devices are pumped according to various embodiments. The lower band edge modes, which are predicted to have the lowest net gain coefficients, do not appear in the experimental emission spectra. FIG. 5D shows a plot of voltage (in volts or V)/intensity (in arbitrary units or a.u.) as a function of current density (in kilo-Amperes per square centimetre or kA/cm²) illustrating the light-current-voltage (L-I-V) curve for the a=31 μm sample according to various embodiments; and (inset) a plot of intensity as a function of frequency (in terahertz or THz) showing an emission spectrum at the laser roll-over point according to various embodiments. The L-I-V curve of the other sample also behaves similarly. The intensities may be obtained by integrating over only the emission peak of the photonic Majorana zero mode. From the experimental L-I-V curves in FIG. 5D, it can be seen that the lasing threshold is around 1.6 kA/cm² for both samples. The intensity of the Majorana lasing peak is about 41 times higher than the strongest UBE peak (side mode suppression ratio (SMSR) of over 16 dB), possibly aided by the UBE frequency being located in the tail of the gain region.

The far-field beam profile was probed using a custom-mode intensity scanner apparatus shown in FIG. 6A. FIG. 6A is an image showing the experimental setup for far-field beam measurements according to various embodiments. The diverged laser beam generated by the quantum cascade laser (QCL) 602 is collimated by a lens 604 with focal length 5 cm, and collected by a THz Golay cell detector 606 (after passing through polarizer 608). To achieve a better image signal-to-noise ratio, the a=31 μm sample was employed due to its higher emitting power, and the pump pulse was further increased to 900 ns. Numerical calculations predict that the Majorana mode produces a CV beam with a doughnut-shaped far-field intensity profile (FIG. 6B). The experimentally obtained intensity profile is in good agreement (FIG. 6C). FIG. 6B shows a numerically calculated intensity profile according to various embodiments. FIG. 6C shows an experimentally obtained intensity profile according to various embodiments.

The axial asymmetry of the beam profile is due largely to a slight ellipticity of the air holes due to fabrication imperfections (this anisotropy was included in the numerical calculations of FIG. 6B; see Supplementary Information below for details).

Aside from the intensity profile, the electric field vector in the CV beam winds around the vortex core (FIG. 6B), forming a nontrivial topology. This can be observed by using a linear polarizer to filter the cross-polarized components.

FIG. 6D shows (left) a plot of intensity (in arbitrary units or a.u.) as a function of frequency (in terahertz or THz) illustrating results polarized-resolved emission spectra obtained by inserting a wire-grid polarizer with polarization angle of 45° between the focal lens and the terahertz detector according to various embodiments; and (right) numerically calculated (upper) and experimentally measured (lower) intensity patterns of the polarized-resolved emission spectra obtained according to various embodiments. FIG. 6E shows (left) a plot of intensity (in arbitrary units or a.u.) as a function of frequency (in terahertz or THz) illustrating results polarized-resolved emission spectra obtained by inserting a wire-grid polarizer with polarization angle of 135° between the focal lens and the terahertz detector according to various embodiments; and (right) numerically calculated (upper) and experimentally measured (lower) intensity patterns of the polarized-resolved emission spectra obtained according to various embodiments.

Numerical calculations show that doing so divides the far-field beam into two lobes with orientations slightly deviating from the polarizer direction (FIGS. 6D-E, upper right panels). As mentioned above, a wire-grid-based linear polarizer is inserted between the collimating lens and the Golay cell detector. With the linear polarizer rotated by 45° and 135°, far-field profiles very similar to the calculation results were obtained (FIGS. 6D-E, lower right panels).

Various embodiments may relate to an electrically pumped THz laser based on photonic Majorana zero mode, which forms a cylindrical vector beam with nonzero polarization winding. The laser emission may be dominated by the mid-gap Majorana zero modes, with a single weak high band edge mode (16 dB SMSR). The winding of the CV beam may be intrinsically tied to the vorticity of the Kekulé modulation on the photonic lattice, demonstrating how 2D topological modes can affect the topological features of the laser light in the far field. Due to the monolithic design, such laser devices may be easily integrated onto photonic chips, which is promising for applications in high-bandwidth wireless communications, THz microscopy, and other applications for THz vector beams. Various embodiments may emit a CV beam, unlike a prior reference which relates to an optically pumped near-infrared laser exhibiting pure linear polarization.

### Device Fabrication

A THz QCL wafer with a three-well resonant-phonon GaAs/Al_{0.15}Ga_{0.85}As design was used. The gain curve spans from 2.9 THz to 3.8 THz, verified by the emission spectrum envelope of a ridge laser fabricated on the same wafer. The topological cavities were patterned onto the wafer using the standard metal-semiconductor-metal configuration, as shown in FIG. 3A.

The fabrication process began with metal (titanium (Ti)/gold (Au) 20/700 nm) deposition by an electron-beam evaporator onto the THz QCL wafer and an n+-doped GaAs host substrate, followed by Au/Au thermo-compression wafer bonding. Wafer polishing and selective wet etching (ammonium hydroxide (NH₃·H₂O)/hydrogen peroxide (H₂O₂)/water (H₂O)=3/57/120 ml) were sequentially conducted to remove the THz QCL substrate down to an etch-stop layer. The etch-stop layer was then removed by hydrogen fluoride (49% cc.) solution, and the QCL active region was exposed for subsequent microfabrication. A 300 nm SiO₂ insulation layer was deposited onto the THz QCL wafer using plasma enhanced chemical vapor deposition (PECVD), followed by optical lithography and reactive-ion etching (RIE) to define the pumping area. The photonic structure patterns were transferred onto the THz QCL wafer by optical lithography, with deposition and lift-off to define the top metal or electrode layer (Ti/Au/Ti/SiO₂, 20/300/20/400 nm), with the SiO₂ layer used as a hard mask for the electrode during the etching of active region. With the top metal layer as a hard mask, the photonic structures were formed by reactive ion etching (RIE) dry etching through the active region with a gas mixture of BCl₃/CH₄/Cl=100/20/5 standard cubic centimeters per minute. The top metal layer (remnant thickness ˜300 nm) was retained as a top contact for current injection. The host substrate was covered by a Ti/Au (15/200 nm) layer as bottom contact. The SEM was used to capture the etching side wall image and calibrate the air hole size. Finally, the THz QCL chip was cleaved into small pieces, indium-soldered onto a copper heatsink, wire-bonded and attached to a cryostat cold finger for characterization.

The SEM was used to capture the etching side wall image and calibrate the air hole size. Finally, the THz QCL chip was cleaved into small pieces, indium-soldered onto a copper heatsink, wire-bonded and attached to a cryostat cold finger for characterization.

### Characterization

For the emission spectrum measurements, the fabricated QCLs were mounted in a helium-gap-steam cryostat with temperature stabilized at 9 K and driven by an electrical pulse generator with repetition rate 10 kHz and pulse width 500 ns. The spectra were captured by a Fourier transform infrared spectrometer (FTIR, Bruker Vertex 80 series) with a room-temperature deuterated triglycine sulphate (DTGS) detector. The spectral resolution is 0.08 cm⁻¹. A scanning setup was employed for far-field beam profile characterization. Intensity measurements were performed with a THz Golay cell detector (TYDEX GC-1T, collection aperture size is 11 mm) mounted on a 15 cm arm. Before the measurement, a home-developed alignment technique was used to align the laser, collimating lens, and the detector based on the principle of light diffraction (see Supplementary Information below for details). To improve the signal-to-noise ratio, the vortex laser was driven by a pump current with 10 kHz repetition rate and 900 ns pulse width, and another 15 Hz electrical modulation was further imposed for lock-in amplification of the detector signal. To further analyse the beam profile, a THz wire-grid polarizer was inserted between the focal lens and Golay cell detector. By continuously rotating the polarizer, both laser spectra and far-field beam profiles were captured.

### Numerical Method

All three-dimensional (3D) full-wave simulations were conducted by the finite-element method-based software COMSOL Multiphysics. In the simulation, the 10-μm-thick QCL active region was treated as a lossless and dispersion free medium with refractive index 3.85. Two gold layers forming the top and bottom contacts have thickness 600 nm, modelled as lossy metal with refractive index 182.67+212.11i. The air hole pattern was generated with the Layout Editor Software.

### Supplementary Information

### Emission Characteristics of Conventional Ridge Lasers

To investigate the gain spectral range of the THz QCL wafer, conventional ridge laser has been fabricated and characterized. FIG. 7A shows a plot of intensity (in arbitrary units or a.u.) as a function of frequency (in terahertz or THz) illustrating the emission characteristics of a conventional laser with length of 1200 μm and width of 100 μm fabricated on the quantum cascade wafer. The gain spectral range is approximately from 2.9 THz to 3.8 THz. This result is employed to estimate the effective refractive index (based on the FSR) of the QCL active region to be around 3.85 at the operation frequency.

FIG. 7B is a plot of gain (per centimetre or cm⁻¹) as a function of frequency (in terahertz or THz) illustrating the calculated gain profile for the quantum cascade laser (QCL) with one period of 44 nm in thickness. The applied electric field is 59 mV that corresponds to 13.4 V if the overall thickness of the real QCL is 10 μm. This is slightly lower than the measured laser devices that is reasonable as the fabricated laser devices have contact Ohmic loss, the grown Au films above/below the QCL exist impurities, and the conduction wires inside the cryostat exist Ohmic loss, and so on. This estimated gain is therefore employed to match the radiative losses in the main text for calculating net gains of each photonic mode.

### The Jackiw-Rossi Model

Various embodiments may include a hexagonal superlattice of air cylinders drilled in an otherwise isotropic QCL slab. A graphene-like tight-binding model may reduce to a two-valley Dirac Hamiltonian close to the Dirac point:

$$[ \begin{matrix}0 & {t}_{1} & 0 & {t}_{2} {e}^{i \vec{k} \cdot {\vec{a}}_{1}} & 0 & {t}_{1} \\ {t}_{1} & 0 & {t}_{1} & 0 & {t}_{2} {e}^{i \vec{k} \cdot {\vec{a}}_{2}} & 0 \\ 0 & {t}_{1} & 0 & {t}_{1} & 0 & {t}_{2} {e}^{i \vec{k} \cdot {\vec{a}}_{3}} \\ {t}_{2} {e}^{- i \vec{k} \cdot {\vec{a}}_{1}} & 0 & {t}_{1} & 0 & {t}_{1} & 0 \\ 0 & {t}_{2} {e}^{- i \vec{k} \cdot {\vec{a}}_{2}} & 0 & {t}_{1} & 0 & {t}_{1} \\ {t}_{1} & 0 & {t}_{2} {e}^{- i \vec{k} \cdot {\vec{a}}_{3}} & 0 & {t}_{1} & 0\end{matrix} ] . \qquad ( 1 )$$

where t₁ and t₂ represent the intra-and intercell interactions between the neighbouring lattice sites, respectively, [symbol] is the in-plane wave vector; [symbol] ₁, [symbol] ₂, and [symbol] ₃ are the three lattice vectors with z,31 ₃= [symbol] ₂− [symbol] ₁.

FIG. 8 shows the bulk band structures calculated from Equation (1). FIG. 8 shows the band structure of the photonic lattice according to various embodiments with different relative hopping amplitudes of t₁ and t₂. For the hoppings t₁=t₂, the cylinders create a honeycomb channel for wave propagation, which leads to the formation of two branches (valleys) of Dirac-cone dispersive states outside of the unperturbed band. However, for t₁≠t₂, the intervalley coupling is realized by introducing a finite mass term, which opens a bandgap at the Γ point. Specifically, for the inter-supercell hopping is larger than the intra-supercell hopping (t₁>t₂), the system shows topological trivial property, while for the inter-supercell hopping is smaller than the intra-supercell hopping (t₁<t₂), a band inversion is overserved that characterizes a topological phase transition.

The intervalley coupling by breaking the symmetry with fixed modulation phase may be considered. This needs a modulation in the radius of the air cylinders drilled in the QCL slab. Periodic boundary condition is therefore applied to the unit cell structures, and the corresponding radius at each site under modification is given as

$$( r ) = {R}_{0} + Δ R ( r ) cos [ K \cdot r + θ ] . \qquad ( 2 )$$

Here r=(0,0), (a/√3,0), (a/2√3, a/2), (−a/2√3, a/2), (−a/√3, 0), (−a/2√3, −a/2), and (a/2√3, −a/2). The variation of cylinder radius modifies the hopping amplitude t_{1,2} in the low-energy model by a certain δt(r). The form of R(r) thus modulates the (real) hoppings as t(r)=t₀−δt(r) cos[K·r+θ]=t₀+[Δ(r)e^{iK·r}+Δ(r)e^{-iK·r}], where t₀=t_{1,2}, and

$$Δ ( r ) = - \frac{1}{2} δ ( r ) {e}^{i θ}$$

is the band opening. Therefore, the band gap opening due to intervalley coupling is mainly controlled by the modulation phase θ, as shown in FIGS. 9A-B.

FIG. 9A shows the bulk band structures at fixed phases from 0 to 2π with a step of π/6 according to various embodiments. FIG. 9B shows a plot of frequency (a/λ₀) as a function of modulation phase (θ) illustrating the band diagrams of the bulk band structures according to various embodiments. Interestingly, the supercell corresponds to the topological phase transition (t₁<t₂) in FIG. 8 for a given modulation phase θ=0°, and it corresponds to trivial phase (t₁>t₂) in FIG. 8 for a given modulation phase θ=180°, respectively.

### Cylindrical Air Holes

To fabricate the samples, the ultraviolet (UV) lithography and the dry etching process was used to drill air holes through the III-V semiconductor materials. After the dry etching, it's clearly observed that residual still exist on the side walls of the air cylinders. To remove these residuals, the final laser devices were cleaned by a mixture of H₂SO₄/H₂0₂/H₂0 with the ratio of 1/8/80. It was found that the etching depth, size expansion, and undercut were closely related to the air hole radius. For air hole with smaller radius, the etching rate is smaller due to the experience that a larger aspect ratio slows down the removal of etching by-products and the replenishment of etching gases and acid. Therefore, the smaller air holes are featured with slightly less etching depth, smaller size expansion and etching undercut, as shown in FIG. 10. FIG. 10 shows scanning electron microscopy (SEM) images of (a) the fabricated samples before acid etching according to various embodiments; and (b) the fabricated samples after acid etching according to various embodiments. The scale bar indicates 5 μm.

It was also found that the air holes were not well patterned. The exact shape is slightly distorted to be elliptical with ratio of long axis divided by short axis as 1.05, and orientation along y-axis, which leads to slight lattice anisotropy, as shown in FIG. 11. The ratio of semi-major axis over semi-minor axis is given by the averaged maximum diameter over the minimum diameter that is directly given by the microscope.

In addition, the microscopic image of a real fabricated laser device was analysed to estimate the averaged radius variation ΔR=ΔR+δR=(1+k)ΔR+δR₀, which can be fitted by a linear function with slope k=0.0203 and δR₀=0.1635 μm, as shown in FIG. 11. FIG. 11 shows a plot of diameter of expansion compared to mask as a function of measured diameter by field emission scanning electron microscopy (FESEM) illustrating the fitting of the linear function to the measured values according to various embodiments, with the inset showing the five regions for the fabricated sample according to various embodiments analysed by the microscope and compared to the designed mask. Taking the linear expansion of air holes, lattice anisotropy, as well as realistic metal losses into account, all the eigen-modes are calculated by the Finite-element method.

### Inversion Symmetry Breaking

The eigenmodes are numerically calculated using the COMSOL Multiphysics software, as shown in FIGS. 12A-B, where both laser devices, i.e., lattice constant of a=31 μm and a=30 μm, were calculated. FIG. 12A shows (left) plots of Q-factor as a function of frequency (in terahertz or THz) and (right) plots of Purcell factor as a function of frequency (in terahertz or THz) of the sample with lattice constant of 31 μm according to various embodiments illustrating, from bottom to top, the calculated eigenmodes of perfect electric conductor (PEC) cladded Dirac-vortex cavity without expansion, PEC cladded Dirac-vortex cavity with expansion, gold (Au) Drude model cladded Dirac-vortex cavity with expansion and radius of air holes in quantum cascade wafer-radius of air holes in gold layers (r_{QCL}-r_{Au})=400 nm, gold (Au) Drude model cladded Dirac-vortex cavity with expansion, anisotropy (semi-major axis by semi-minor axis equals to 1.05, and orientation along y-axis). FIG. 12B shows (left) plots of Q-factor as a function of frequency (in terahertz or THz) and (right) plots of Purcell factor as a function of frequency (in terahertz or THz) of the sample with lattice constant of 30 μm according to various embodiments illustrating, from bottom to top, the calculated eigenmodes of perfect electric conductor (PEC) cladded Dirac-vortex cavity without expansion, PEC cladded Dirac-vortex cavity with expansion, gold (Au) Drude model cladded Dirac-vortex cavity with expansion and r_{QCL}-r_{Au}=400 nm, gold (Au) Drude model cladded Dirac-vortex cavity with expansion, anisotropy (semi-major axis by semi-minor axis equals to 1.05, and orientation along y-axis).

Initially, the passive Dirac-vortex cavity is treated as the perfect electric conductor (PEC) cladded PhC, and the drilled air cylinder holes are perfectly matched with the given parameters (FIG. 4A). For the sample with a=31 μm, a mid-gap state at 3.19 THz (˜3.26 THz for sample a=30 μm), i.e., the photonic analogue of Majorana zero mode bound to a vortex, is clearly observed between two doubly degenerated band edges (at 3.05 THz (˜3.11 THz for sample a=30 μm) and 3.38 THz (˜3.45 THz for sample a=30 μm), respectively) opened by the intervalley coupling discussed above. Then the linear expansion of the air cylinder holes is taken into consideration. The metallic claddings are gold film with thickness of 600 nm that is depicted by the Drude model. In addition, the radiuses of drilled air cylinder holes in the QCL slab have a 300-nm expansion compared to the drilled air cylinder holes in the top Au electrode contact. Finally, the air cylinder holes are all treated as elliptical shapes with ratio of long axis divided by short axis as 1.05, and major axis along y-axis, as shown in FIGS. 11A-B. The lower and upper band edges (LBEs and UBEs) show splitting due to the elliptical air holes in the realistic laser device introduce anisotropy, which also increases the radiative losses to decrease the Q-factor of the Dirac-vortex cavity. All the modes are now visualized at around 3.16 THz for the LBEs (˜3.32 THz for sample a=30 μm), 3.34 THz for the Dirac-vortex mode (˜3.5 2 THz for sample a=30 μm), and around 3.52 THz for the UBEs (˜3.73 THz for sample a=30 μm). To evaluate the lasing capabilities of both BE states and mid-gap Dirac-vortex state, the Purcell factors were calculated. As finite size of the lattice is investigated, the Purcell factor is equivalent to the local density of state that takes care two key parameters of a cavity: quality factor Q and modal volume V. In a realistic system, the total Q-factor is determined by three types of loss mechanisms, the intrinsic radiation loss 1/Q_{rad}, the material absorption loss 1/Q_{abs}, and the radiative loss due to surface roughness 1/Qₛᵤᵣ. Therefore, the total loss rate reads 1/Qₜₒₜ=1/Q_{rad}+1/Q_{abs}+1/Qₛᵤᵣ. By using acid to remove the residuals on the surface of our sample, the scattering loss due to surface roughness is minimized, as shown in FIG. 10. The mode volume, defined as

$$V = \frac{\int ε {\vert E \vert}^{2} dV}{max ( ε {\vert E \vert}^{2} )}$$

with ε as the dielectric permittivity of QCL, is a value to measure the volume within which the mode is confined. The Purcell factor is therefore written as

$$F = \frac{3 Q}{4 {π}^{2} V} {( \frac{λ}{{n}_{eff}} )}^{3} \qquad ( 3 )$$

Here λ is the vacuum wavelength and

$${n}_{eff} = \sqrt{\frac{\int ε {\vert E \vert}^{2} dV}{max ( ε {\vert E \vert}^{2} )}}$$

is the effective index of refraction. Therefore, even though the Q-factor of the Dirac-vortex state seems not as high as these sitting at the UBE, its bounded feature to the vortex core indicates the smallest mode volume and the highest Purcell factor, as shown in FIGS. 12A-B. These have been proved to fit very well with the experimentally measured laser spectra as described above.

Even though the lattice is hexagonally distributed and the intervalley phase is smoothly interpolated, the discrete and nonperiodic features of the spatially arranged air cylinder holes imply that the system sustains radiative coupling to the radiation continuum due to the inversion symmetry breaking of the intervalley phase. FIG. 13 shows (top panel) the electric field z-component at the middle of the Dirac-vortex cavity according to various embodiments; (middle panel) Fourier transformed electric field (FT(E_{z})) according to various embodiments; and (bottom panel) the far-field beam patterns according to various embodiments. It can be clearly observed from the top panel of FIG. 13 that the cavity still tightly confines the field even when there is anisotropy present in the system and lossy materials are taken into consideration. The Fourier transformed fields FT{E_{z}} are plotted to show that the Dirac-vortex mode indeed exists within the light cone, as shown in the middle panel of FIG. 13. In addition, the radiation capability increases from (a) to (d) in FIG. 13 as the centre portion is getting stronger even when air hole size expansion and anisotropy are taken into numerical calculations. Moreover, compared to the cavities with circular air cylinders, the laser device with elliptical air cylinders shows asymmetrical Fourier transformed fields FT{E_{z}}, as shown by the middle panel of FIG. 13(d). Therefore, the radiative far field also presents asymmetric beam profile. Overall, all the far-field beams present doughnut-shaped beam profiles, and the vector electric field (black arrows) indicates that the CV beam under investigation is spiral polarization.

### Enhanced Side Mode Suppression Ratio (SMSR)

Due to the broad gain spectral range, the QCL supports stimulated emission of vortex mode as well as band edge mode. Moving the higher band edge out of the gain spectral range would suppress the unwanted mode and enhance the mode purity of the vortex emission, which can be conveniently achieved through scaling the hexagonal lattice. An attempt has been made by reducing the lattice constant from 31 μm to 30 μm, of which the vortex mode as well as higher band edge mode are found to be blue-shifted by ˜0.15 THz. The output intensity decreases for sample with a=30 μm due to the slightly misalignment of Dirac-vortex mode and gain profile through its pump voltage shares same trends as the sample a=31 μm. However, as the latter mode is almost located at the gain spectrum tail, the SMSR is elevated to be above 16 dB, as shown in FIGS. 14A-B. FIG. 14A shows a plot of voltage (in volts or V)/intensity (in arbitrary units or a.u.) as a function of current density (in kiloamperes per square centimetre or kA/cm²) illustrating the light-current-voltage (L-I-V) curve comparison between two samples with lattice constants of 31 μm and 30 μm according to various embodiments. FIG. 14B shows a plot of intensity (in arbitrary units or a.u.) as a function of frequency (in terahertz or THz) illustrating the emission spectra measured at similar bias voltage and pump current density for vortex lasers with lattice constants of 31 μm and 30 μm according to various embodiments.

### Robustness Against Defects

To investigate the topological robustness of the laser device according to various embodiments, THz QCL samples with winding number of w=±1 were fabricated and pumped at their highest gain. Then the pulse duration is modulated from 100 ns to 800 ns that correspond to duty cycles of 0.1% to 0.8% as the repetition rate is set as 10 kHz, as shown in FIGS. 15A-B. FIG. 15A is a three-dimensional (3D) plot of intensity (in arbitrary units or a.u. as a function of frequency (in terahertz or THz) and pulse duration (in nanoseconds or ns) illustrating the robustness of the single-mode quantum cascade laser (QCL) with winding number +1 without defect according to various embodiments. FIG. 15B is a three-dimensional (3D) plot of intensity (in arbitrary units or a.u. as a function of frequency (in terahertz or THz) and pulse duration (in nanoseconds or ns) illustrating the robustness of the single-mode quantum cascade laser (QCL) with winding number −1 with accidental defects due to fabrications according to various embodiments, with the inset showing the scanning electron microscopy (SEM) images of the defects.

The stable lasing with single peak requests that the pulse width is larger than 200 ns for both sample with different winding numbers. However, a random defect with size around one period is accidentally generated in the intervalley coupling (phase control) domain for the sample with minus winding number, as shown in FIG. 15B. Even so, the w=−1 sample also shows robust lasing at same frequency that is around 3.51 THz as the w=+1 sample. In the passive system, this topological robustness has been discussed by employing symmetry-preserved defects in the vortex core, but here, the topological robustness is shown to be still preserved when there is a randomly generated defect in the intervalley coupling domain without any symmetric characteristics.

### Polarization-Resolved Lasing Spectra

Before mapping the far-field beam pattern, the polarization-resolved lasing spectra were characterized, as shown in FIGS. 16A-B. FIG. 16A shows a plot of polarization angle (in degrees or °) as a function of frequency (in terahertz or THz) of the polarization lasing spectra for a sample with lattice constant a=30 μm according to various embodiments. FIG. 16B shows a plot of intensity (in arbitrary units or a.u.) as a function of frequency (in terahertz or THz) of the polarization lasing spectra for the sample with lattice constant a=30 μm according to various embodiments. It can be clearly observed that the Dirac-vortex laser peak robustly dominates the emission spectrum. The slight variation of the intensity is due to the anisotropy of fabrication.

### Sample Alignment For Far-field Mapping

The physics of light diffraction has substantial importance for fundamental sciences and industry applications. Here, the Littrow configuration to align the QCL, focal lens, and Golay cell detector is employed. When a light with wavelength of λ is incident on the Dirac-vortex topological cavity with angle of θᵢ to the normal, the diffracted beams are observed at angle of θ_{d}, thus

$$sin ( {θ}_{i} ) - sin ( {θ}_{d} ) = m \frac{λ}{a} ,$$

where a is the lattice constant, and m is the order of diffraction. If θᵢ=−θ_{d}, we have

$$sin ( {θ}_{d} ) = m \frac{λ}{2 a} .$$

The diffracted beam corresponding to order m then exactly retraces the incident beam. The zero-order diffraction m=0, corresponding to specular reflection (θ_{d}=0), is employed to get the experimental setup aligned.

FIG. 17 shows (a) a schematic of a focal system being inserted between the terahertz (THz) quantum cascade laser (QCL) sample and iris, where the focused light should be on same position of the THz QCL sample according to various embodiments; and (b) a schematic of an electrically pumped quantum cascade laser (QCL) with the laser pointer replaced by a terahertz (THz) Golay cell detector for far-field mapping according to various embodiments.

A laser point is fixed on the mechanical arms was incident on the QCL, and the diffracted beams show hexagonal patterns. However, the zero-order diffraction shows maximum intensity at the centre. Therefore, by setting an iris between the laser pointer and QCL (inside cryostat chamber), the zero-order diffraction would be a specular reflection and would exactly project the maximum intensity to the hole of the iris so that the THz QCL may align. Then a focal lens was also inserted between the iris and the THz QCL sample, as shown in FIG. 17(a). The laser pointer may get focused and projected on the same position of THz QCL sample. Finally, the laser pointer was replaced by a THz Golay cell detector, as shown in FIG. 17(b).

### Power Measurement For The Dirac-Vortex Laser

The QCL power was measured by a terahertz powermeter, Gentec-EO T-Rad with detector head of THZ9B-BL-DZ-D0. The THz detector has a collection aperture of 0.9 mm in diameter.

FIG. 18 shows a setup for focusing the diverged beam of the Dirac-vortex quantum cascade laser (QCL) according to various embodiments.

To improve the collection efficiency, the laser emission was focused by two parabolic mirrors, as shown in FIG. 18. Samples with lattice constant of a=30 μm and a=31 μm and winding number w=+1 were measured. The pump pulse width was 900 ns and repetition rate were 10 kHz, which were also used for far-field measurement. In a dry nitrogen purging circumstance, the measured average powers are 5.8 μW for sample with a=31 μm and 3.8 μW for sample with a=30 μm, respectively. Therefore, the peak power of the compact laser source can reach 1.29 mW for sample a=3 1 μm without accounting for collection efficiency of ˜30%, which was also employed to map the far-field beam profile.

1. A topological laser comprising:
a photonic structure configured to generate a laser beam upon electrical pumping of the photonic structure;
wherein the laser beam is based on photonic Majorana zero mode;
wherein the laser beam is a cylindrical vector beam; and
wherein the topological laser is configured to provide single mode operation.

2. The topological laser according to claim 1,
wherein the photonic structure comprises a first metal layer and a second metal layer; and
wherein the photonic structure comprises a photonic lattice between the first metal layer and the second metal layer.

3. The topological laser according to claim 2, wherein the first metal layer and the photonic lattice include a plurality of air holes extending from the first metal layer to the photonic lattice.

4. The topological laser according to claim 3, wherein each of the plurality of air holes has a radius dependent on a position of the air hole according to a Kekulé modulation.

5. The topological laser according to claim 3, wherein the plurality of air holes forms a honeycomb lattice arrangement.

6. The topological laser according to claim 2, wherein the photonic structure further comprises an electrically insulating layer surrounding the first metal layer.

7. The topological laser according to claim 6, wherein the insulating layer comprises silicon dioxide or silicon nitride.

8. The topological laser according to claim 2, wherein the first metal layer and the second metal layer comprise gold or copper.

9. The topological laser according to claim 2, wherein the photonic lattice is a quantum cascade laser (QCL) wafer.

10. The topological laser according to claim 1, wherein a center of the laser beam has a polarization singularity.

11. The topological laser according to claim 1, wherein the topological laser is a terahertz (THz) semiconductor laser.

12. A method of forming a topological laser, the method comprising:
forming a photonic structure configured to generate a laser beam upon electrical pumping of the photonic structure;
wherein the laser beam is based on photonic Majorana zero mode;
wherein the laser beam is a cylindrical vector beam; and
wherein the topological laser is configured to provide single mode operation.

13. The method according to claim 12, wherein forming the photonic structure comprises forming a photonic lattice between a first metal layer and a second metal layer.

14. The method according to claim 13, wherein forming the photonic structure comprises forming a plurality of air holes extending from the first metal layer to the photonic lattice.

15. The method according to claim 14, wherein each of the plurality of air holes has a radius dependent on a position of the air hole according to a Kekulé modulation.

16. The method according to claim 14, wherein the plurality of air holes forms a honeycomb lattice arrangement.

17. The method according to claim 13, wherein forming the photonic structure further comprises forming an electrically insulating layer surrounding the first metal layer.

18. The method according to claim 17, wherein the insulating layer comprises silicon dioxide or silicon nitride.

19. The method according to claim 13, wherein the first metal layer and the second metal layer comprise gold or copper.

20. (canceled)

21. The method according to claim 12, wherein a center of the laser beam has a polarization singularity.

22. (canceled)
